(19) United States
(12) Patent Application Publication
(10) Pub. No.: US 2025/0338692 A1
(43) Pub. Date: Oct. 30, 2025

(54) DISPLAY DEVICE, METHOD OF MANUFACTURING DISPLAY DEVICE, AND ELECTRONIC DEVICE INCLUDING DISPLAY DEVICE

(71) Applicant: SAMSUNG DISPLAY CO., LTD., YONGIN-SI (KR)

(72) Inventors: SEUNG-WON PARK, YONGIN-SI (KR); JUO NAM, YONGIN-SI (KR); KAWON PAK, YONGIN-SI (KR); KYUNGSIG LEE, YONGIN-SI (KR); SEUNGHEE JANG, YONGIN-SI (KR); JAEBOK CHANG, YONGIN-SI (KR)

(21) Appl. No.: 19/001,838

(22) Filed: Dec. 26, 2024

(30) Foreign Application Priority Data
Apr. 30, 2024 (KR) 10-2024-0057565

(51) Int. Cl. H10H 29/851; H10H 29/01; H10H 29/856

(52) U.S. Cl. CPC H10H 29/8514; H10H 29/012; H10H 29/0361; H10H 29/856

(57) ABSTRACT

A display device includes: a substrate; a light emitting element disposed on the substrate; a bank layer disposed on the light emitting element and defining an opening overlapping the light emitting element in a plan view; a color conversion pattern disposed inside the opening and having an outer side surface including a contact portion that contacts an upper surface of the bank layer; and a capping layer covering the bank layer and the color conversion pattern. An angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

### CROSS-REFERENCE TO RELATED APPLICATION

This patent application claims priority under 35 USC § 119 to Korean Patent Application No. 10-2024-0057565, filed on Apr. 30, 2024, in the Korean Intellectual Property Office, the disclosure of which is incorporated by reference in its entirety herein.

### 1. TECHNICAL FIELD

The present disclosure is directed to a display device, a method of manufacturing the display device, and an electronic device including the display device.

### 2. DISCUSSION OF RELATED ART

A display device is a connection medium between a user and information. Examples of such display devices include a liquid crystal display (“LCD”) device, an organic light emitting diode (“OLED”) display device, a plasma display panel (“PDP”) device and a quantum dot display device.

However, these display devices may develop cracks due to physical impact, thermal stress or manufacturing defects. Such cracks may lead to loss of visual clarity due to distorted images, dead pixels and color bleeding, and may reduce touch sensitivity in display devices that include a touch panel.

In OLED displays, each pixel is self-emissive, meaning it generates its own light. Cracks in OLED panels can disrupt electrical connections between the pixels and the circuitry that controls them. As a result, pixels in the cracked area may stop emitting light, leading to darks spots, regions of light loss and images presented with inaccurate colors.

Thus, there is a need for a display device that is more resistant to cracking and reduces light loss.

### SUMMARY

Embodiments provide a display device including a capping layer and a method of manufacturing the same, which may prevent cracks from developing and increase reliability.

Embodiments provide an electronic device including the display device.

A display device according to an embodiment of the present disclosure includes: a substrate, a light emitting element, a bank layer, a color conversion pattern, and a capping layer. The substrate includes a light emitting area and a light blocking area surrounding the light emitting area. The light emitting element is disposed on the substrate in the light emitting area. The bank layer is disposed on the light emitting element in the light blocking area and defines an opening overlapping the light emitting element in a plan view. The color conversion pattern is disposed inside the opening on the light emitting element in the light emitting area and has an outer side surface including a contact portion that contacts an upper surface of the bank layer. The capping layer covers the bank layer and the color conversion pattern. An angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

In an embodiment, the outer side surface of the color conversion pattern may at least partially overlap the bank layer in the plan view.

In an embodiment, the color conversion pattern may include a photosensitive organic material.

In an embodiment, the capping layer may include an inorganic insulating material.

In an embodiment, the capping layer may be disposed along profiles of the bank layer and

the color conversion pattern.

In an embodiment, the display device may further include a reflective film disposed between the bank layer and the color conversion pattern, where the reflective film includes a metal.

In an embodiment, the display device may further include a reflective film protection layer disposed between the reflective film and the color conversion pattern.

In an embodiment, the display device may further include a reflective bank disposed between the bank layer and the color conversion pattern and including a scattering particle.

In an embodiment, the bank layer may include a first bank layer and a second bank layer disposed on the first bank layer. The outer side surface of the color conversion pattern may include the contact portion that contacts an upper surface of the second bank layer. The second tangent may be a tangent from the contact portion to the upper surface of the second bank layer in the direction away from the color conversion pattern.

In an embodiment, the light emitting element may include a first semiconductor layer disposed on the substrate, an active layer disposed on the first semiconductor layer, and a second semiconductor layer disposed on the active layer.

In an embodiment, the light emitting area may include a first light emitting area, a second light emitting area, and a third light emitting area that emit lights of different colors. The light emitting element may be disposed in each of the first light emitting area, the second light emitting area, and the third light emitting area. The color conversion pattern may include a first color conversion pattern overlapping the light emitting element in the first light emitting area in the plan view, a second color conversion pattern overlapping the light emitting element in the second light emitting area in the plan view, and a transmission pattern overlapping the light emitting element in the third light emitting area in the plan view.

In an embodiment, the first color conversion pattern may convert light emitted from the light emitting element into light of a first color. The second color conversion pattern may convert the light emitted from the light emitting element into light of a second color. The transmission pattern may transmit the light emitted from the light emitting element.

A display device according to an embodiment of the present disclosure includes: a substrate; a light emitting element; a bank layer; a bank protection layer; a color conversion pattern; and a capping layer. The substrate includes a light emitting area and a light blocking area surrounding the light emitting area. The light emitting element is disposed on the substrate in the light emitting area. The bank layer is disposed on the light emitting element in the light blocking area and defines an opening overlapping the light emitting element in a plan view. The bank protection layer covers an upper surface of the bank layer and a side surface of the bank layer. The color conversion pattern is disposed inside the opening on the light emitting element in the light emitting area and has an outer side surface including a contact portion that contacts an upper surface of the bank protection layer. The capping layer covers the bank protection layer and the color conversion pattern. An angle between a first tangent from the contact portion to the outer side surface of the color conversion pattern and a second tangent from the contact portion to the upper surface of the bank protection layer in a direction away from the color conversion pattern is greater than or equal to about 90 degrees and less than about 180 degrees.

In an embodiment, the outer side surface of the color conversion pattern may at least partially overlap the bank layer in the plan view.

In an embodiment, the capping layer may include an inorganic insulating material.

In an embodiment, the capping layer may be disposed along profiles of the bank protection layer and the color conversion pattern.

In an embodiment, the display device may further include a reflective film disposed between the bank protection layer and the color conversion pattern, where the reflective layer includes a metal.

In an embodiment, the display device may further include a reflective film protection layer disposed between the reflective film and the color conversion pattern.

In an embodiment, the bank layer may include a first bank layer and a second bank layer disposed on the first bank layer. The bank protection layer may cover a side surface of the first bank layer, a side surface of the second bank layer, and an upper surface of the second bank layer.

A method of manufacturing a display device according to an embodiment of the present disclosure includes: forming a light emitting element on a substrate in a light emitting area; forming a bank layer on the substrate in a light blocking area to define an opening that overlaps the light emitting element in a plan view; forming a preliminary layer to cover the bank layer; patterning the preliminary layer to form a color conversion pattern disposed inside the opening and having an outer side surface including a contact portion that contacts an upper surface of the bank layer; and forming a capping layer covering the bank layer and the color conversion pattern. An angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

In an embodiment, the patterning the preliminary layer may include exposing the preliminary layer and developing the exposed preliminary layer to form the color conversion pattern.

In an embodiment, the capping layer may include an inorganic insulating material.

In an embodiment, the capping layer may be formed along profiles of the bank layer and the color conversion pattern.

In an embodiment, the method may further include forming a reflective film to contact a side surface of the bank layer and include a metal before forming the preliminary layer.

In an embodiment, the method may further include forming a reflective film protection layer covering the reflective film before forming the preliminary layer.

In an embodiment, the method may further include forming a reflective bank to contact a side surface of the bank layer and include a scattering particle before forming the preliminary layer.

In an embodiment, the light emitting element may include a first semiconductor layer disposed on the substrate, an active layer disposed on the first semiconductor layer, and a second semiconductor layer disposed on the active layer.

An electronic device according to an embodiment of the present disclosure includes: a display device including a light emitting element; and a power module configured to provide power to the display device. The display device includes: a substrate, the light emitting layer, a bank layer, a color conversion pattern, and a capping layer. The substrate includes a light emitting area and a light blocking area surrounding the light emitting area. The light emitting element is disposed on the substrate in the light emitting area. The bank layer is disposed on the light emitting element in the light blocking area and defines an opening overlapping the light emitting element in a plan view. The color conversion pattern is disposed inside the opening on the light emitting element in the light emitting area and has an outer side surface including a contact portion that contacts an upper surface of the bank layer. The capping layer covers the bank layer and the color conversion pattern. An angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

A display device according to an embodiment of the present disclosure may include a bank layer disposed on a light emitting element in a light blocking area and defining an opening overlapping the light emitting element in a plan view, a color conversion pattern disposed inside the opening on the light emitting element in a light emitting area and having an outer side surface including a contact portion that contacts an upper surface of the bank layer, and a capping layer covering the bank layer and the color conversion pattern. An angle between a first tangent from the contact portion to the outer side surface of the color conversion pattern and a second tangent from the contact portion to the upper surface of the bank layer in a direction away from the color conversion pattern may be greater than or equal to about 90 degrees and less than about 180 degrees.

Accordingly, in a process of forming the capping layer, a crack defect that occurs near a connection portion where a first portion of the capping layer disposed along a profile of the color conversion pattern and a second portion of the capping layer disposed along a profile of the bank layer are connected can be prevented.

In addition, when the crack defect that occurs in the capping layer is prevented, the luminance retention rate of the display device can be increased. In other words, a decrease in the luminance of the display device as a driving time of the display device increases can be suppressed.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is a cross-sectional view illustrating a color conversion pattern of FIG. 2.

FIG. 4 is an enlarged cross-sectional view of area A of FIG. 2.

FIG. 5 is a cross-sectional view illustrating a display device according to a comparative example.

FIG. 6 is a cross-sectional view illustrating a display device according to an embodiment of the present disclosure.

FIG. 7 is a cross-sectional view illustrating a display device according to an embodiment of the present disclosure.

FIG. 8 is a cross-sectional view illustrating a display device according to an embodiment of the present disclosure.

FIG. 9 is a cross-sectional view illustrating a display device according to an embodiment of the present disclosure.

FIG. 10 is a flowchart of a method of manufacturing a display device according to an embodiment of the present disclosure.

FIGS. 11, 12, 13, 14, 15, 16, 17, 18, and 19 are cross-sectional views illustrating the method of manufacturing the display device of FIG. 10.

FIG. 20 is a block diagram of an electronic device according to an embodiment of the present disclosure.

FIG. 21 is a schematic diagram of an electronic device according to various embodiments.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted.

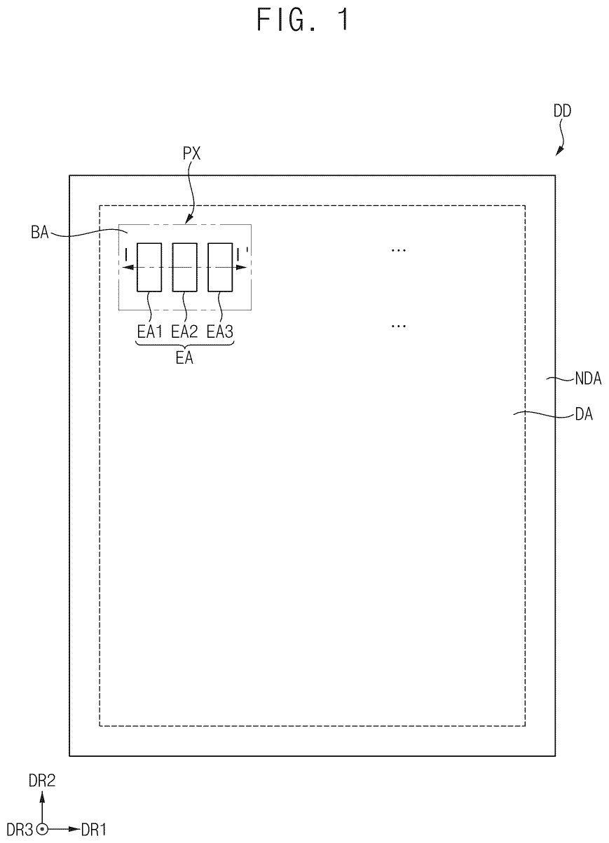

FIG. 1 is a plan view illustrating a display device according to an embodiment of the present disclosure.

In this specification, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2. As used herein the “plan view” is a view in the third direction DR3.

Referring to FIG. 1, the display device DD according to an embodiment of the present disclosure may include a display area DA and a non-display area NDA.

The display area DA may be defined as an area that displays an image by generating light or adjusting the transmittance of light provided from an external light source. A plurality of pixels PX may be disposed in the display area DA. Each of the pixels PX may generate light in response to a driving signal. For example, the pixels PX may be disposed repeatedly along the first direction DR1 and the second direction DR2.

The display area DA may include a light emitting area EA and a light blocking area BA. Specifically, each of the pixels PX may include the light emitting area EA, and the light emitting area EA may include a first light emitting area EA1, a second light emitting area EA2, and a third light emitting area EA3. Each of the first to third light emitting areas EA1, EA2, EA3 may be defined as an area that emits light. In FIG. 1, each of the pixels PX is illustrated as including three light emitting areas EA1, EA2, EA3, but the present disclosure is not limited thereto. For example, each of the pixels PX may include four or more light emitting areas.

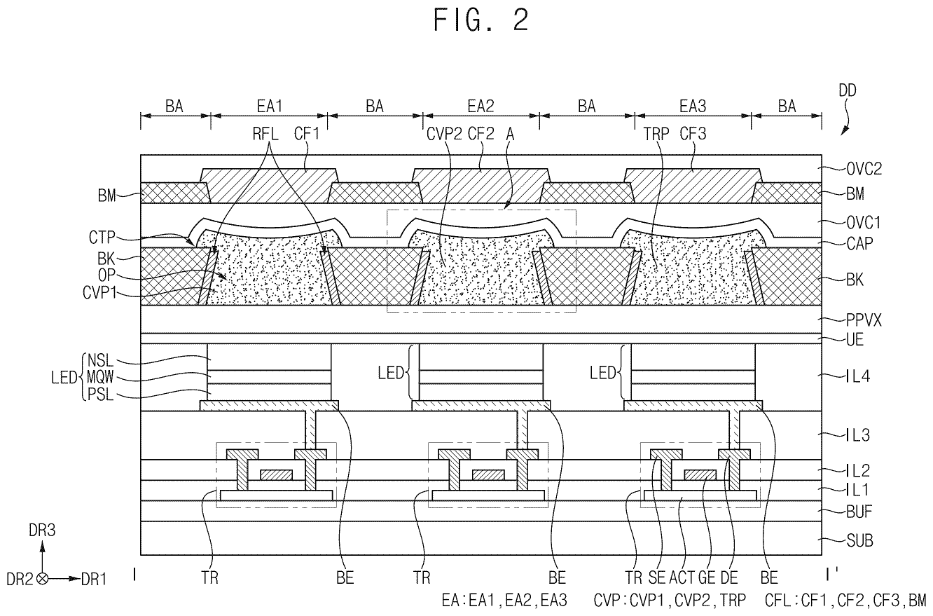

A light emitting element (LED, refer to FIG. 2) that emits light of a preset color may be disposed in each of the first to third light emitting areas EA1, EA2, EA3. For example, the light emitting element may emit blue light, but the present disclosure is not limited thereto.

The first light emitting area EA1 may emit light of a first color. Specifically, the first light emitting area EA1 may convert light emitted from the light emitting element into light of the first color and may emit the light of the first color. For example, the first color may be red, but the present disclosure is not limited thereto.

The second light emitting area EA2 may emit light of a second color. Specifically, the second light emitting area EA2 may convert the light emitted from the light emitting element into light of the second color and may emit the light of the second color. For example, the second color may be green, but the present disclosure is not limited thereto.

The third light emitting area EA3 may emit light of a third color. Specifically, the third light emitting area EA3 may emit the light emitted from the light emitting element. For example, the third color may be blue, but the present disclosure is not limited thereto.

For example, each of the first to third light emitting areas EA1, EA2, EA3 may have a rectangular planar shape. However, the present disclosure is not limited thereto. In another example, each of the first to third light emitting areas EA1, EA2, EA3 may have any one of a triangular planar shape, a circular planar shape and an elliptical planar shape.

In an embodiment, the first to third light emitting areas EA1, EA2, EA3 have the same size (or area) as each other. However, the present disclosure is not limited thereto, and the first to third light emitting areas EA1, EA2, EA3 may have different sizes as each other.

The light blocking area BA may be defined as an area that does not emit light. For example, the light blocking area BA may surround the first to third light emitting areas EA1, EA2, EA3 in a plan view.

The non-display area NDA may be defined as an area that does not display an image. The non-display area NDA may surround at least a portion of the display area DA in a plan view. For example, the non-display area NDA may entirely surround the display area DA in a plan view. A driving chip and a plurality of pads that provide the driving signal to the pixels PX may be disposed in the non-display area NDA. In an embodiment, no pixel is located in the non-display area NDA.

In an embodiment, the display device DD is a micro-LED display device. In this case, the light emitting element may be a micro light emitting diode. However, the present disclosure is not limited thereto. For example, the display device DD may be any one of an organic light emitting display device, a liquid crystal display device, an organic light emitting diode on silicon (“OLEDoS”), an inorganic light emitting display (“ILED”) device, and a quantum dot emitting display (“QED”) device.

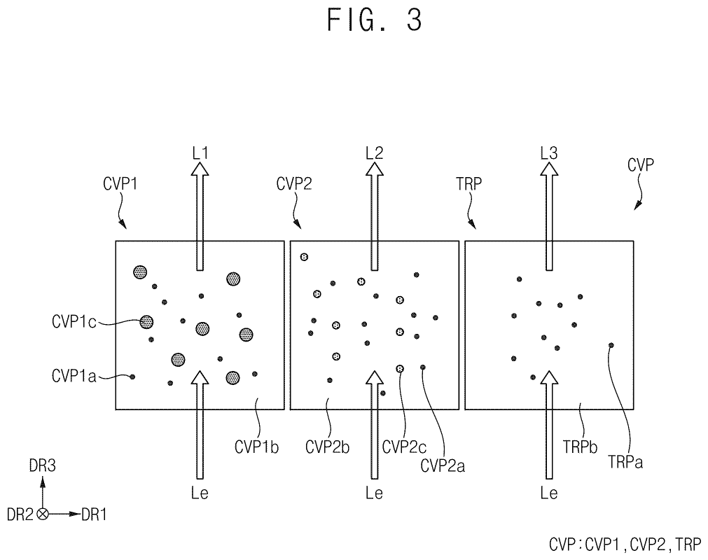

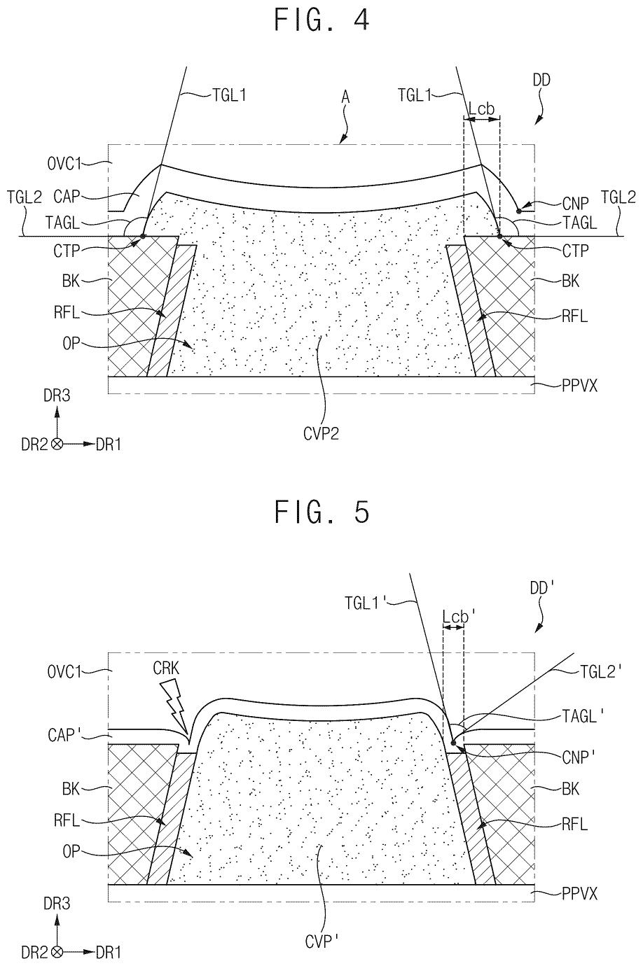

FIG. 2 is a cross-sectional view taken along line I-I′ of FIG. 1. FIG. 3 is a cross-sectional view illustrating a color conversion pattern of FIG. 2. FIG. 4 is an enlarged cross-sectional view of area A of FIG. 2.

Referring to FIGS. 2, 3, and 4, the display device DD according to an embodiment of the present disclosure includes a substrate SUB, a buffer layer BUF, a thin film transistor TR, first to third insulating layers IL1, IL2, IL3, a lower electrode BE, a light emitting element LED, a fourth insulating layer IL4, an upper electrode UE, a pixel protection layer PPVX, a bank layer BK, a reflective film RFL, a color conversion pattern CVP, a capping layer CAP, a first flattening layer OVC1, a color filter layer CFL, and a second flattening layer OVC2. The color conversion pattern CVP may reduce light loss and enable display of colors with high efficiency. The capping layer CAP may protect the color conversion pattern CVP from developing cracks.

The thin film transistor TR may include an active pattern ACT, a gate electrode GE, a source electrode SE, and a drain electrode DE. The light emitting element LED may include a first semiconductor layer PSL, an active layer MQW, and a second semiconductor layer NSL. In an embodiment, the color conversion pattern CVP includes a first color conversion pattern CVP1, a second color conversion pattern CVP2, and a transmission pattern TRP. In an embodiment, the color filter layer CFL includes a first color filter CF1, a second color filter CF2, a third color filter CF3, and a light blocking pattern BM.

The substrate SUB may include a transparent material or an opaque material. For example, the substrate SUB may be formed of a transparent resin substrate. A polyimide substrate may be an example of the transparent resin substrate. In this case, the polyimide substrate may include a first organic layer, a first barrier layer, a second organic layer, etc. In an embodiment, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The buffer layer BUF may be disposed on the substrate SUB. The buffer layer BUF may prevent diffusion of metal atoms or impurities from the substrate SUB into an upper structure (e.g., the thin film transistor TR, the light emitting element LED, etc.). In addition, the buffer layer BUF may enable the active pattern ACT to have a uniform or substantially uniform shape by controlling a heat transfer rate during a crystallization process for forming the active pattern ACT. In addition, the buffer layer BUF may serve to increase flatness of a surface of the substrate SUB when the surface of the substrate SUB is not uniform. For example, the buffer layer BUF may include an inorganic insulating material. In an alternative embodiment, the buffer layer BUF is omitted.

The active pattern ACT may be disposed on the buffer layer BUF. The active pattern ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active pattern ACT may include a source area, a drain area, and a channel area positioned between the source area and the drain area.

The first insulating layer IL1 may be disposed on the active pattern ACT and the buffer layer BUF. For example, the first insulating layer IL1 may cover the active pattern ACT on the buffer layer BUF and may have a substantially flat upper surface without having a step shaped portion around the active pattern ACT. The first insulating layer IL1 may include an inorganic insulating material. Examples of the inorganic insulating material that may be used as the first insulating layer IL1 include silicon oxide (SiOₓ), silicon nitride (SiNₓ), silicon oxynitride (SiOₓN_{y}), etc. They may be used alone or in combination with each other. The first insulating layer IL1 may electrically insulate the active pattern ACT from the gate electrode GE.

The gate electrode GE may be disposed on the first insulating layer IL1. The gate electrode GE may overlap the channel area of the active pattern ACT. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in combination with each other.

The second insulating layer IL2 may be disposed on the gate electrode GE and the first insulating layer IL1. For example, the second insulating layer IL2 may cover the gate electrode GE on the first insulating layer IL1 and may have a substantially flat upper surface without including a step shaped portion around the gate electrode GE. The second insulating layer IL2 may include an inorganic insulating material. Examples of the inorganic insulating material that may be used as the second insulating layer IL2 may include silicon oxide (SiOₓ), silicon nitride (SiNₓ), silicon oxynitride (SiOₓN_{y}), etc. They may be used alone or in combination with each other. The second insulating layer IL2 may electrically insulate the gate electrode GE from the source electrode SE. In addition, the second insulating layer IL2 may electrically insulate the gate electrode GE from the drain electrode DE.

The source electrode SE and the drain electrode DE may be disposed on the second insulating layer IL2. The source electrode SE may be connected to the source area of the active pattern ACT through a contact hole penetrating the first insulating layer IL1 and the second insulating layer IL2. The drain electrode DE may be connected to the drain area of the active pattern ACT through a contact hole penetrating the first insulating layer IL1 and the second insulating layer IL2. Each of the source electrode SE and the drain electrode DE may include a metal, an alloy, a metal nitride, a conductive metal oxide, a transparent conductive material, etc. They may be used alone or in combination with each other.

Accordingly, the thin film transistor TR including the active pattern ACT, the gate electrode GE, the source electrode SE, and the drain electrode DE may be formed.

The third insulating layer IL3 may be disposed on the second insulating layer IL2. For example, the third insulating layer IL3 may be disposed with a relatively large thickness to sufficiently cover the source electrode SE and the drain electrode DE on the second insulating layer IL2. The third insulating layer IL3 may include an organic insulating material. Examples of the organic insulating material that may be used as the third insulating layer IL3 include a photoresist, a polyacryl-based resin, a polyimide-based resin, a polyamide-based resin, a siloxane-based resin, an acryl-based resin, an epoxy-based resin, etc. These may be used alone or in combination with each other.

The lower electrode BE may be disposed on the third insulating layer IL3. The lower electrode BE may be electrically connected to the drain electrode DE through a contact hole penetrating the third insulating layer IL3. Accordingly, the lower electrode BE may be electrically connected to the thin film transistor TR. In addition, the lower electrode BE may be electrically connected to the first semiconductor layer PSL. The lower electrode BE may include a metal, an alloy, a metal nitride, a conductive metal oxide, a transparent conductive material, etc. For example, the lower electrode BE may include a transparent conductive oxide. In this case, the lower electrode BE may include indium tin oxide (“ITO”), but the present disclosure is not limited thereto. For example, the lower electrode BE may serve as an anode electrode.

The light emitting element LED may be disposed in the light emitting area EA on the substrate SUB. Specifically, the light emitting element LED may be disposed in each of the first light emitting area EA1, the second light emitting area EA2, and the third light emitting area EA3 on the lower electrode BE. The light emitting element LED may emit light of a preset color. For example, the light emitting element LED may emit blue light, but the present disclosure is not limited thereto.

In an embodiment, the light emitting element LED is a micro light emitting diode. The light emitting element LED may include the first semiconductor layer PSL, the active layer MQW, and the second semiconductor layer NSL. The active layer MQW may be disposed between the first semiconductor layer PSL and the second semiconductor layer NSL.

The first semiconductor layer PSL may be disposed on the lower electrode BE. The first semiconductor layer PSL may include a p-type semiconductor. For example, the first semiconductor layer PSL may include p-type doped AlGaInN, GaN, AlGaN, InGaN, AlN, InN, etc. These may be used alone or in combination with each other. The first semiconductor layer PSL may be doped with a p-type dopant. The p-type dopant may include magnesium (Mg), zinc (Zn), calcium (Ca), selenium (Se), barium (Ba), etc. For example, the first semiconductor layer PSL may include p-GaN doped with p-type Mg.

The active layer MQW may be disposed on the first semiconductor layer PSL. The active layer MQW may generate light by the coupling of electron-hole pairs according to an electrical signal applied through the first semiconductor layer PSL and the second semiconductor layer NSL.

The active layer MQW may include a material having a single quantum well structure or a multi-quantum well structure. For example, when the active layer MQW includes a material with a multi-quantum well structure, the active layer MQW may have a structure in which well layers and barrier layers are alternately stacked. The well layers may include InGaN, and the barrier layers may include GaN or AlGaN. However, the present disclosure is not limited thereto.

The active layer MQW may include different group III to group V semiconductor materials depending on the wavelength of emitted light. For example, when the semiconductor materials included in the active layer MQW include indium (In), the color of the emitted light may vary depending on the content of indium (In). When the content of indium (In) decreases, the wavelength band of the emitted light may shift to a red wavelength band, and when the content of indium (In) increases, the wavelength band of the emitted light may shift to a blue wavelength band.

The second semiconductor layer NSL may be disposed on the active layer MQW. The second semiconductor layer NSL may include an n-type semiconductor. For example, the second semiconductor layer NSL may include n-type doped AlGaInN, GaN, AlGaN, InGaN, AlN, InN, etc. These may be used alone or in combination with each other. The second semiconductor layer NSL may be doped with an n-type dopant. The n-type dopant may include silicon (Si), germanium (Ge), tin (Sn), etc. For example, the second semiconductor layer NSL may include n-GaN doped with n-type Si.

The fourth insulating layer IL4 may be disposed on the third insulating layer IL3. The fourth insulating layer IL4 may cover the lower electrode BE and the light emitting element LED. The fourth insulating layer IL4 may include an inorganic insulating material or an organic insulating material.

The upper electrode UE may be disposed on the second semiconductor layer NSL and the fourth insulating layer IL4. The upper electrode UE may be entirely disposed in the first to third light emitting areas EA1, EA2, EA3 and the light blocking area BA. The upper electrode UE may be electrically connected to the second semiconductor layer NSL. The upper electrode UE may include a metal, an alloy, a metal nitride, a conductive metal oxide, a transparent conductive material, etc. For example, the upper electrode UE may include a transparent conductive oxide. In this case, the upper electrode UE may include indium tin oxide (“ITO”), but the present disclosure is not limited thereto. For example, the upper electrode UE may serve as a cathode electrode.

The pixel protection layer PPVX may be disposed on the upper electrode UE. The pixel protection layer PPVX may cover the upper electrode UE. The pixel protection layer PPVX may include an inorganic insulating material or an organic insulating material.

The bank layer BK may be disposed in the light blocking area BA on the light emitting element LED. Specifically, the bank layer BK may be disposed in the light blocking area BA on the pixel protection layer PPVX. The bank layer BK may partition the first to third light emitting areas EA1, EA2, EA3. In other words, the bank layer BK may define a plurality of openings OP that partition the first to third light emitting areas EA1, EA2, EA3. Each of the openings OP may overlap the light emitting element LED in a plan view. Accordingly, the bank layer BK may be disposed in the light blocking area BA and may not be disposed in the first to third light emitting areas EA1, EA2, EA3. For example, the bank layer BK may have a reverse-taper cross-sectional shape. In this case, a width (e.g., a length in the first direction DR1) of an upper surface of the bank layer BK may be greater than a width of a lower surface of the bank layer BK. However, the present disclosure is not limited thereto.

The bank layer BK may include an inorganic material or an organic material including a light blocking material with a black color. For example, the bank layer BK may include black pigments, black dyes, carbon black, etc. These may be used alone or in combination with each other.

In an embodiment, the reflective film RFL is disposed between the bank layer BK and the color conversion pattern CVP. Specifically, the reflective film RFL may be disposed between the bank layer BK and the first color conversion pattern CVP1, between the bank layer BK and the second color conversion pattern CVP2, and between the bank layer BK and the transmission pattern TRP. The reflective film RFL may contact a side surface of the bank layer BK. In an embodiment, the reflective layer RFL includes a metal having a high light reflectivity. For example, the reflective film RFL may include aluminum (Al) or silver (Ag), but the present disclosure is not limited thereto. In an embodiment, a thickness of the reflective film RFL in the third direction DR3 is less than a thickness of the bank layer BK in the third direction DR3. In an embodiment, an upper surface of the reflective film RFL is lower than an upper surface of the bank layer BK.

As the reflective film RFL includes a metal having a high light reflectivity, the reflective film RFL may reflect light incident on the reflective film RFL from the light emitting element LED. In addition, the reflective film RFL may reflect light incident on the reflective film RFL from the color conversion pattern CVP. Light reflected from the reflective film RFL may be incident on the color conversion pattern CVP. In other words, since the light reflected from the reflective film RFL may be reused in the color conversion pattern CVP, light efficiency can be increased. In an alternative embodiment, the reflective film RFL is omitted.

The color conversion pattern CVP may be disposed in the light emitting area EA on the light emitting element LED. Specifically, the color conversion pattern CVP may be disposed inside the openings OP defined by the bank layer BK. In an embodiment, the color conversion pattern CVP contacts the reflective film RFL. The color conversion pattern CVP may include the first color conversion pattern CVP1, the second color conversion pattern CVP2, and the transmission pattern TRP.

The first color conversion pattern CVP1 may be disposed inside the opening OP in the first light emitting area EA1. The first color conversion pattern CVP1 may overlap the light emitting element LED in the first light emitting area EA1 in a plan view.

The second color conversion pattern CVP2 may be disposed inside the opening OP in the second light emitting area EA2. The second color conversion pattern CVP2 may overlap the light emitting element LED in the second light emitting area EA2 in a plan view.

The transmission pattern TRP may be disposed inside the opening OP in the third light emitting area EA3. The transmission pattern TRP may overlap the light emitting element LED in the third light emitting area EA3 in a plan view.

As illustrated in FIG. 3, the first color conversion pattern CVP1 may include first quantum dots CVP1c that are excited by light Le emitted from the light emitting element LED and emit light L1 of a first color. In addition, the first color conversion pattern CVP1 may further include a first photosensitive polymer CVP1b in which first scattering particles CVP1a are dispersed. The first color conversion pattern CVP1 may convert the light Le emitted from the light emitting element LED into the light L1 of the first color. For example, the light Le emitted from the light emitting element LED may be blue light, and the light L1 of the first color may be red light.

The second color conversion pattern CVP2 may include second quantum dots CVP2c that are excited by the light Le emitted from the light emitting element LED and emit light L2 of a second color. In addition, the second color conversion pattern CVP2 may further include a second photosensitive polymer CVP2b in which second scattering particles CVP2a are dispersed. The second color conversion pattern CVP2 may convert the light Le emitted from the light emitting element LED into the light L2 of the second color. For example, the light L2 of the second color may be green light.

The transmission pattern TRP may include a third photosensitive polymer TRPb in which third scattering particles TRPa are dispersed. The transmission pattern TRP may transmit the light Le emitted from the light emitting element LED. For example, the blue light Le emitted from the light emitting element LED may pass through the transmission pattern TRP and be output as blue light L3.

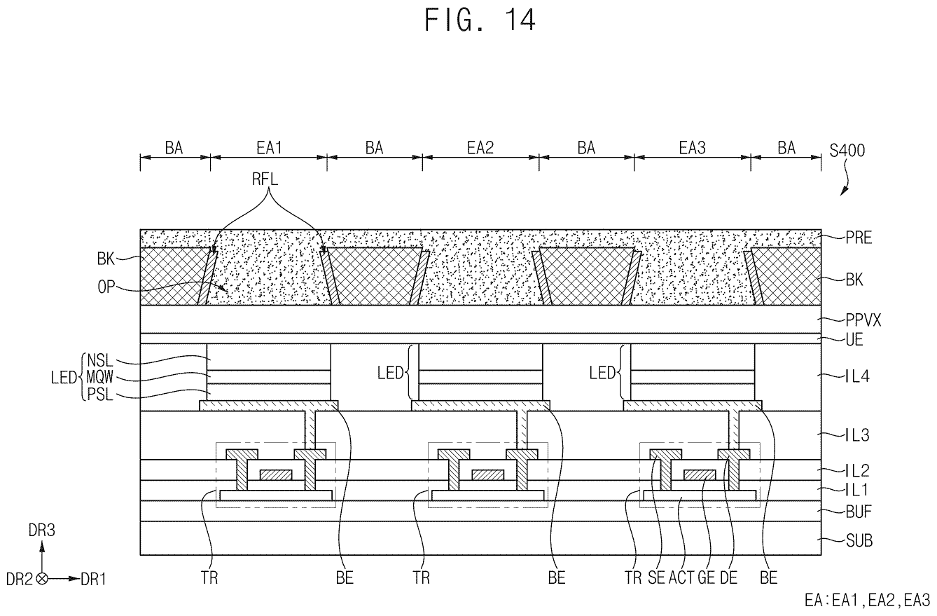

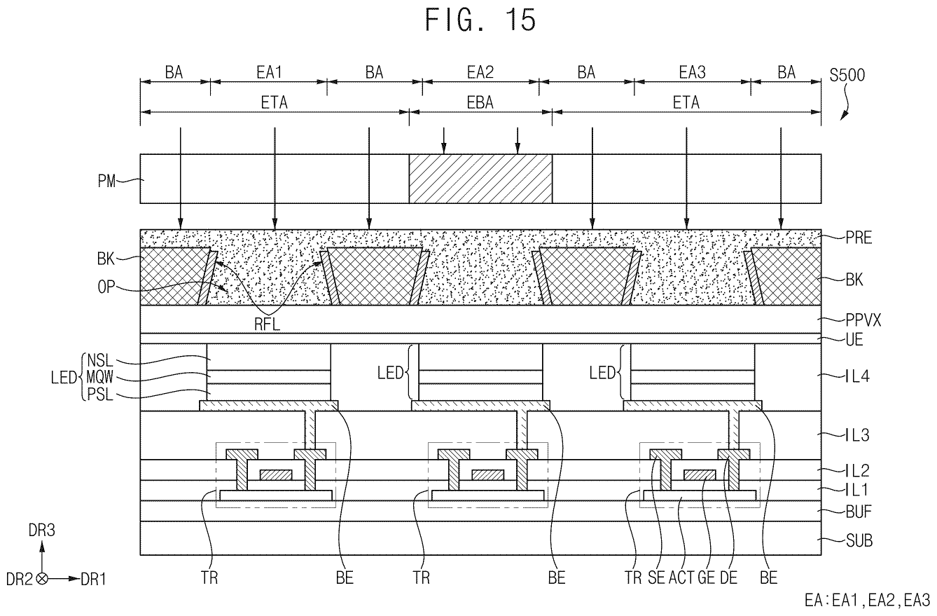

In exemplary embodiments, each of the first color conversion pattern CVP1, the second color conversion pattern CVP2, and the transmission pattern TRP may include a photosensitive organic material. Each of the first color conversion pattern CVP1, the second color conversion pattern CVP2, and the transmission pattern TRP may be formed by a photolithography process. A detailed description thereof will be described below with reference to FIGS. 14, 15, 16, and 17.

In exemplary embodiments, as illustrated in FIGS. 2 and 4, the color conversion pattern CVP includes a contact portion CTP that contacts the upper surface of the bank layer BK. Specifically, the contact portion CTP may be defined as a portion where an outer side surface of the color conversion pattern CVP contacts the upper surface of the bank layer BK. The outer side surface of the color conversion pattern CVP may at least partially overlap the bank layer BK in a plan view.

The first color conversion pattern CVP1, the second color conversion pattern CVP2, and the transmission pattern TRP may have substantially the same or symmetrical shape. Hereinafter, the description will focus on the second color conversion pattern CVP2. The description of the second color conversion pattern CVP2 may replace the description of the first color conversion pattern CVP1 and the transmission pattern TRP.

As illustrated in FIG. 4, the contact portion CTP may be defined as a portion where an outer side surface of the second color conversion pattern CVP2 and the upper surface of the bank layer BK contact each other. A first tangent line TGL1 may be defined as a tangent line (or tangent) drawn from the contact portion CTP to the outer side surface of the second color conversion pattern CVP2. A second tangent line TGL2 may be defined as a tangent line (or tangent) drawn from the contact portion CTP to the upper surface of the bank layer BK. Specifically, the second tangent line TGL2 may be defined as a tangent line drawn from the contact portion CTP to the upper surface of the bank layer BK in a direction away from the second color conversion pattern CVP2. For example, the direction may extend outward from the second color conversion pattern CVP2 towards the upper surface of the bank layer. A tangent angle TAGL may be defined as an angle between the first tangent line TGL1 and the second tangent line TGL2. In an exemplary embodiment, the tangent angle TAGL is greater than or equal to 90 degrees (or about 90 degrees) and less than about 180 degrees (or about 180 degrees). In a particular embodiment, the tangent angle TAGL is greater than or equal to 90 degrees (or about 90 degrees) and less than or equal to 150 degrees (or about 150 degrees). In a more particular embodiment, the tangent angle TAGL is greater than or equal to 90 degrees (or about 90 degrees) and less than or equal to 120 degrees (or about 120 degrees).

The capping layer CAP may be disposed on the bank layer BK and the color conversion pattern CVP. In an embodiment, the capping layer CAP is entirely disposed in the first to third light emitting areas EA1, EA2, EA3 and the light blocking area BA. The capping layer CAP may cover the bank layer BK and the color conversion pattern CVP.

In exemplary embodiments, the capping layer CAP includes an inorganic insulating material. For example, the capping layer CAP may include silicon oxide (SiOₓ), silicon nitride (SiNₓ), silicon oxynitride (SiOₓN_{y}), etc. These may be used alone or in combination with each other. However, the present disclosure is not limited thereto.

In an embodiment, the capping layer CAP is disposed along the profiles or a peripheral edge of the bank layer BK and the color conversion pattern CVP. Specifically, the capping layer CAP may include a first portion and a second portion connected to the first portion. The first portion of the capping layer CAP may be disposed along the profile or peripheral edge of the color conversion pattern CVP. The second portion of the capping layer CAP may be disposed along the profile or peripheral edge of the bank layer BK. Here, as illustrated in FIG. 4, a connection portion CNP may be defined as a portion where the first portion of the capping layer CAP and the second portion of the capping layer CAP are connected or contact one another. An angle between a tangent line drawn from the connection portion CNP to an outer side surface of the first portion of the capping layer CAP and a tangent line drawn from the connection portion CNP to an upper surface of the second portion of the capping layer CAP may be equal or substantially equal to the tangent angle TAGL.

As described above, at least a portion of the color conversion pattern CVP may contact the upper surface of the bank layer BK, and the tangent angle TAGL may be greater than or equal to about 90 degrees and less than about 180 degrees. In this case, in the process of forming the capping layer CAP, a crack defect that occurs near the connection portion CNP where the first portion disposed along the profile of the color conversion pattern CVP and the second portion disposed along the profile of the bank layer BK are connected can be prevented.

As the crack defect that occurs in the capping layer CAP is prevented, the luminance retention rate of the display device DD can be increase. In other words, a decrease in the luminance of the display device DD as a driving time of the display device DD increases can be suppressed.

In an embodiment, a first flattening layer OVC1 is disposed on the capping layer CAP. The first flattening layer OVC1 may include an inorganic insulating material and/or an organic insulating material. The first flattening layer OVC1 can flatten a step formed by the bank layer BK and the color conversion pattern CVP.

The color filter layer CFL may be disposed on the first flattening layer OVC1. The color filter layer CFL may include the first to third color filters CF1, CF2, CF3 and the light blocking pattern BM.

The light blocking pattern BM may partition the first to third light emitting areas EA1, EA2, EA3. In other words, the light blocking pattern BM may define a plurality of openings that partition the first to third light emitting areas EA1, EA2, EA3. Accordingly, the light blocking pattern BM may be disposed in the blocking area BA and may not be disposed in the first to third light emitting areas EA1, EA2, EA3. The light blocking pattern BM may include an inorganic material or an organic material including a light blocking material with a black color.

The first to third color filters CF1, CF2, CF3 may be disposed inside the openings defined by the light blocking pattern BM, respectively.

The first color filter CF1 may overlap the light emitting element LED in the first light emitting area EA1 in a plan view. For example, the first color filter CF1 may transmit red light and may absorb or block green light and blue light. Accordingly, red light may be emitted from the first light emitting area EA1. However, the present disclosure is not limited thereto.

The second color filter CF2 may overlap the light emitting element LED in the second light emitting area EA2 in a plan view. For example, the second color filter CF2 may transmit green light and may absorb or block red light and blue light. Accordingly, green light may be emitted from the second light emitting area EA2. However, the present disclosure is not limited thereto.

The third color filter CF3 may overlap the light emitting element LED in the third light emitting area EA3 in a plan view. For example, the third color filter CF3 may transmit blue light and may absorb or block red light and green light. Accordingly, blue light may be emitted from the third light emitting area EA3. However, the present disclosure is not limited thereto.

In an embodiment, a second flattening layer OVC2 is disposed on the color filter layer CFL. The second flattening layer OVC2 may include an inorganic insulating material and/or an organic insulating material. The second flattening layer OVC2 may flatten a step formed by the color filter layer CFL.

A cover window may be disposed on the second flattening layer OVC2. The cover window may include a transparent material to allow light emitted from the light emitting element LED to pass to an outside of the display device DD. For example, the cover window may include glass or plastic. The cover window may serve to cover and protect the display device DD.

FIG. 5 is a cross-sectional view illustrating a display device according to a comparative example.

Referring to FIG. 5, a display device DD′ according to a comparative example includes a pixel protection layer PPVX, a bank layer BK, a reflective film RFL, a color conversion pattern CVP′, a capping layer CAP′, and a first flattening layer OVC1.

The display device DD′ according to the comparative example may be substantially the same as the display device DD described above with reference to FIGS. 1 to 4, except that the color conversion pattern CVP′ is spaced apart from the bank layer BK and has a different tangent angle TAGL′. Hereinafter, redundant descriptions of the display device DD described above with reference to FIGS. 1 to 4 may be omitted or may be summarized.

The color conversion pattern CVP′ is disposed inside an opening OP defined by the bank layer BK. The color conversion pattern CVP′ may contact the reflective film RFL. However, the color conversion pattern CVP′ does not contact an upper surface of the bank layer BK. In other words, the color conversion pattern CVP′ is spaced apart from the bank layer BK. Specifically, an outer side surface of the color conversion pattern CVP′ may be spaced apart from the upper surface of the bank layer BK.

The capping layer CAP′ may be disposed on the bank layer BK and the color conversion pattern CVP′. The capping layer CAP′ may cover the bank layer BK and the color conversion pattern CVP′. The capping layer CAP′ may include an inorganic insulating material.

The capping layer CAP′ may be disposed along the profiles or a peripheral edge of the bank layer BK and the color conversion pattern CVP′. Specifically, the capping layer CAP′ may include a first portion and a second portion connected to the first portion. The first portion of the capping layer CAP′ may be disposed along the profile or a peripheral edge of the color conversion pattern CVP′. The second portion of the capping layer CAP′ may be disposed along the profile or a peripheral edge of the bank layer BK. Here, a connection portion CNP′ may be defined as a portion where the first portion of the capping layer CAP′ and the second portion of the capping layer CAP′ are connected or contact one another. In this case, a crack CRK may occur near the connection portion CNP′ where the first portion disposed along the profile or a peripheral edge of the color conversion pattern CVP′ and the second portion disposed along the profile or a peripheral edge of the bank layer BK are connected or contact one another.

In the display device DD′ according to the comparative example, a first tangent line TGL1′ may be defined as a tangent line drawn from the connection portion CNP′ to an outer side surface of the first portion of the capping layer CAP′. A second tangent line TGL2′ may be defined as a tangent line drawn from the connection portion CNP′ to an upper surface of the second portion of the capping layer CAP′. A tangent angle TAGL′ may be defined as an angle between the first tangent line TGL1′ and the second tangent line TGL2″.

Hereinafter, the effects of the present disclosure will be described below with reference to Table 1 and FIGS. 4 and 5.

The occurrence of cracks in a capping layer and the luminance retention rate were measured in display devices satisfying Comparative Example 1, Comparative Example 2, Embodiment 1, Embodiment 2, Embodiment 3, Embodiment 4, and Embodiment 5. To measure the luminance retention rate, 50,000 nits of blue light was emitted from a lower portion of a color conversion pattern toward the color conversion pattern. The luminance retention rate was measured as the luminance ratio of the luminance of the display device after about 500 hours to the initial luminance of the display device.

Each of the display devices (e.g., the display device DD of FIG. 2) satisfying Embodiment 1, Embodiment 2, Embodiment 3, Embodiment 4, and Embodiment 5 includes the color conversion pattern CVP including the contact portion CTP that contacts an upper surface of the bank layer BK. Specifically, the contact portion CTP is defined as a portion where an outer side surface of the color conversion pattern CVP and the upper surface of the bank layer BK contact each other. The outer side surface of the color conversion pattern CVP at least partially overlaps the bank layer BK. An overlap length Lcb is defined as a length in the first direction DR1 along which the color conversion pattern CVP and the upper surface of the bank layer BK overlap. The tangent angle TAGL is defined as an angle between the first tangent line TGL1 and the second tangent line TGL2 The first tangent line TGL1 is defined as a tangent line drawn from the contact portion CTP to the outer side surface of the color conversion pattern CVP. The second tangent line TGL2 is defined as a tangent line drawn from the contact portion CTP to the upper surface of the bank layer BK in a direction away from the color conversion pattern CVP.

In the display device satisfying Embodiment 1, the overlap length Lcb is about 0 micrometers, and the tangent angle TAGL is about 92 degrees. In the display device satisfying the Embodiment 2, the overlap length Lcb is about 0.5 micrometers, and the tangent angle TAGL is about 100 degrees. In the display device satisfying the Embodiment 3, the overlap length Lcb is about 0.9 micrometers, and the tangent angle TAGL is about 106 degrees. In the display device satisfying the Embodiment 4, the overlap length Lcb is about 1.4 micrometers, and the tangent angle TAGL is about 110 degrees. In the display device satisfying the Embodiment 5, the overlap length Lcb is about 1.8 micrometers, and the tangent angle TAGL is about 112 degrees.

Each of the display devices (e.g., the display device DD′ of FIG. 5) satisfying the Comparative Example 1 and the Comparative Example 2 includes the color conversion pattern CVP′ that does not contact an upper surface of the bank layer BK. An outer side surface of the color conversion pattern CVP′ is spaced apart from the upper surface of the bank layer BK. A separation length Lcb′ is defined as a length in the first direction DR1 along which the outer side surface of the color conversion pattern CVP′ and the upper surface of the bank layer BK are spaced apart. The tangent angle TAGL′ is defined as an angle between the first tangent line TGL1′ and the second tangent line TGL2′. The first tangent line TGL1′ is defined as a tangent line drawn from the connection portion CNP′ to an outer side surface of the first portion of the capping layer CAP′ that is disposed along the profile of the color conversion pattern CVP′. The second tangent line TGL2′ is defined as a tangent line drawn from the connection portion CNP′ to an upper surface of the second portion of the capping layer CAP′ that is disposed along the profile of the bank layer BK.

In the display device satisfying the Comparative Example 1, the separation length Lcb′ is about 0.8 micrometers, and the tangent angle TAGL′ is about 80 degrees. In the display device satisfying the Comparative Example 2, the separation length Lcb′ is about 0.4 micrometers, and the tangent angle TAGL′ is about 85 degrees.

As a result, referring to Table 1 below, cracks occurred in the capping layer CAP′ in the display devices satisfying the Comparative Example 1 and the Comparative Example 2, and no cracks occurred in the capping layer CAP in the display devices satisfying Embodiment 1, Embodiment 2, Embodiment 3, Embodiment 4, and Embodiment 5.

In addition, the luminance retention rate of the display device satisfying the Comparative Example 1 was measured to have a value of about 56%. The luminance retention rate of the display device satisfying the Comparative Example 2 was measured to have a value of about 64%. The luminance retention rate of the display device satisfying Embodiment 1 was measured to have a value of about 85%. The luminance retention rate of the display device satisfying Embodiment 2 was measured to have a value of about 86%. The luminance retention rate of the display device satisfying Embodiment 3 was measured to have a value of about 85%. The luminance retention rate of the display device satisfying Embodiment 4 was measured to have a value of about 87%. The luminance retention rate of the display device satisfying Embodiment 5 was measured to have a value of about 86%.

TABLE 1

| | | | | | luminance |
|---|---|---|---|---|---|
| | separation | overlap | tangent | | retention |
| | length | Length | angle | occurrence | rate |
| | (μm) | (μm) | (degree) | of cracks | (%) |
| Comparative | 0.8 | — | 80 | ◯ | 56 |
| Example 1 | | | | | |
| Comparative | 0.4 | — | 85 | ◯ | 64 |
| Example 2 | | | | | |
| Embodiment 1 | — | 0 | 92 | X | 85 |
| Embodiment 2 | — | 0.5 | 100 | X | 86 |
| Embodiment 3 | — | 0.9 | 106 | X | 85 |
| Embodiment 4 | — | 1.4 | 110 | X | 87 |
| Embodiment 5 | — | 1.8 | 112 | X | 86 |

From these results, it can be seen that the display device DD according to an embodiment of the present disclosure includes the color conversion pattern CVP whose outer side surface may overlap the upper surface of the bank layer BK, and has the tangent angle TAGL of about 90 degrees or more and less than about 180 degrees, so that the crack defects occurring in the capping layer CAP are prevented, and the luminance retention rate of the display device DD is increased.

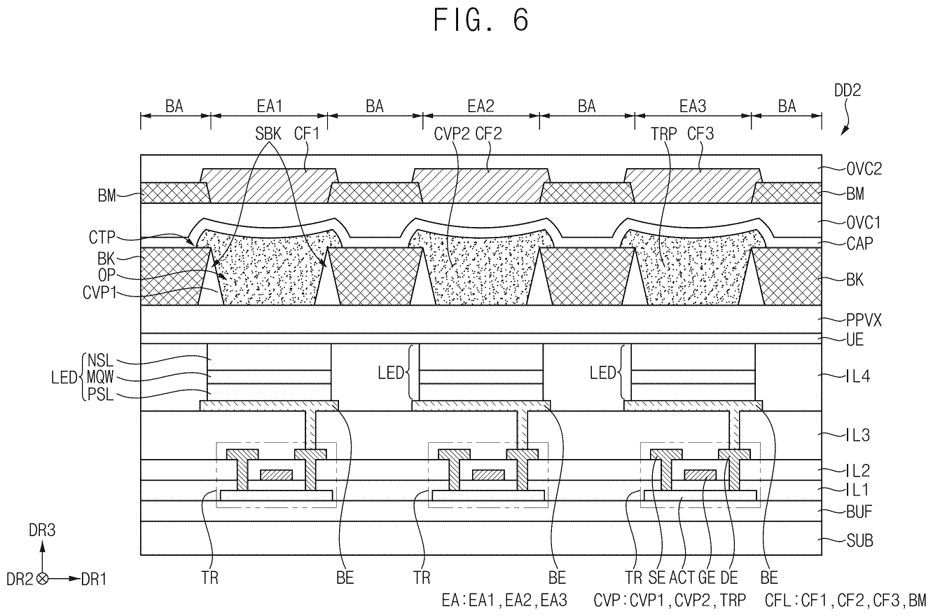

FIG. 6 is a cross-sectional view illustrating a display device according to an embodiment of the present disclosure.

Referring to FIG. 6, a display device DD2 according to an embodiment of the present disclosure includes the substrate SUB, the buffer layer BUF, the thin film transistor TR, the first to third insulating layers IL1, IL2, IL3, the lower electrode BE, the light emitting element LED, the fourth insulating layer IL4, the upper electrode UE, the pixel protection layer PPVX, the bank layer BK, a reflective bank SBK, the color conversion pattern CVP, the capping layer CAP, the first flattening layer OVC1, the color filter layer CFL, and the second flattening layer OVC2.

The display device DD2 may be substantially the same as the display device DD described above with reference to FIGS. 1 to 4, except that the display device DD2 includes the reflective bank SBK instead of the reflective film RFL of FIG. 2. Hereinafter, redundant descriptions of the display device DD described above with reference to FIGS. 1 to 4 may be omitted or may be summarized.

In an embodiment, the reflective bank SBK is disposed between the bank layer BK and the color conversion pattern CVP. Specifically, the reflective bank SBK may be disposed between the bank layer BK and the first color conversion pattern CVP1, between the bank layer BK and the second color conversion pattern CVP2, and between the bank layer BK and the transmission pattern TRP. The reflective bank SBK may contact a side surface of the bank layer BK. In an embodiment, the reflective bank SBK includes scattering particles and a photosensitive polymer in which the scattering particles are dispersed.

As the reflective bank SBK includes the scattering particles, the reflective bank SBK may reflect and/or scatter light incident on the reflective bank SBK from the light emitting element LED. In addition, the reflective bank SBK may reflect and/or scatter light incident on the reflective bank SBK from the color conversion pattern CVP. Light reflected and/or scattered from the reflective bank SBK may be incident on the color conversion pattern CVP. In other words, since the light reflected and/or scattered from the reflective bank SBK may be reused in the color conversion pattern CVP, light efficiency can be increased.

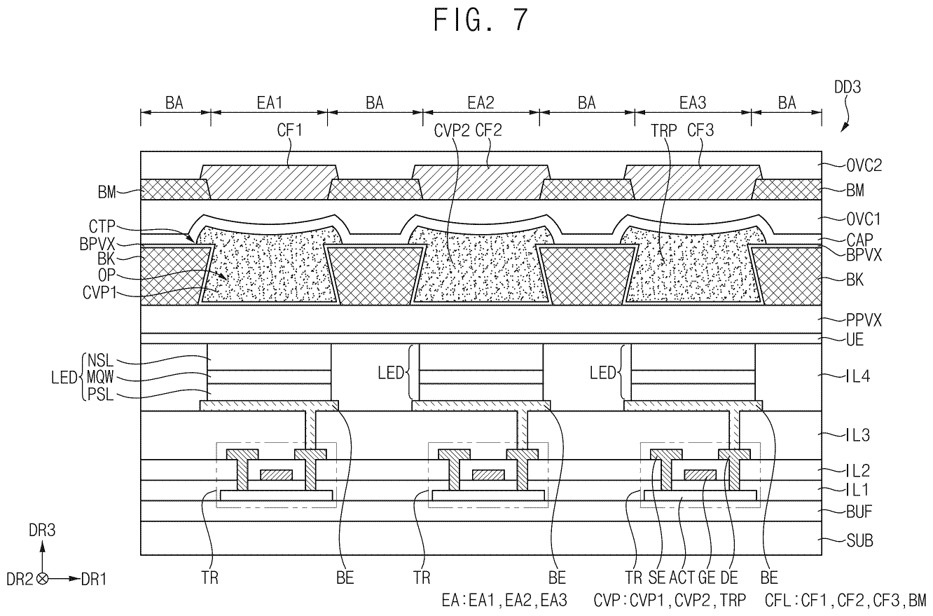

FIG. 7 is a cross-sectional view illustrating a display device according to an embodiment of the present disclosure.

Referring to FIG. 7, a display device DD3 according to an embodiment of the present disclosure includes the substrate SUB, the buffer layer BUF, the thin film transistor TR, the first to third insulating layers IL1, IL2, IL3, the lower electrode BE, the light emitting element LED, the fourth insulating layer IL4, the upper electrode UE, the pixel protection layer PPVX, the bank layer BK, a bank protection layer BPVX, the color conversion pattern CVP, the capping layer CAP, the first flattening layer OVC1, the color filter layer CFL, and the second flattening layer OVC2.

The display device DD3 may be substantially the same as the display device DD described above with reference to FIGS. 1 to 4, except that the display device DD3 includes the bank protection layer BPVX covering the bank layer BK. Hereinafter, redundant descriptions of the display device DD described above with reference to FIGS. 1 to 4 may be omitted or may be summarized.

The bank protection layer BPVX may be disposed on the bank layer BK and the pixel protection layer PPVX. The bank protection layer BPVX may be entirely disposed in the first to third light emitting areas EA1, EA2, EA3 and the light blocking area BA. The bank protection layer BPVX may cover an upper surface of the bank layer BK and a side surface of the bank layer BK. For example, the bank layer BK may include several portions spaced apart from one another in the first direction DR1 and the bank protection layer BPVX may cover these portions. In an embodiment, the bank protection layer BPVX includes an inorganic insulating material. For example, the bank protection layer BPVX may include silicon oxide (SiOₓ), silicon nitride (SiNₓ), silicon oxynitride (SiOₓN_{y}), etc. These may be used alone or in combination with each other. However, the present disclosure is not limited thereto.

In an embodiment, the bank protection layer BPVX is disposed along the profiles or a peripheral edge of the bank layer BK and the pixel protection layer PPVX. The bank protection layer BPVX may block material migration between the bank layer BK and the color conversion pattern CVP.

The display device DD3 may further include a reflective film (e.g., the reflective film RFL of FIG. 2) that increases light efficiency. In this case, the reflective film may be disposed between the bank protection layer BPVX and the color conversion pattern CVP. The reflective film may contact a side surface of the bank protection layer BPVX. For example, the reflective film may be disposed between a side surface of the bank layer BK and a side surface of the color conversion pattern CVP.

The color conversion pattern CVP may be disposed inside the openings OP defined by the bank layer BK. In this case, an outer side surface of the color conversion pattern CVP may include a contact portion CTP that contacts an upper surface of the bank protection layer BPVX. Here, the upper surface of the bank protection layer BPVX may refer to a surface that is disposed on the bank layer BK and is parallel to an upper surface of the bank layer BK. The outer side surface of the color conversion pattern CVP may at least partially overlap the bank layer BK in a plan view.

A tangent angle may be defined as an angle between a first tangent line and a second tangent line. The first tangent line may be defined as a tangent line drawn from the contact portion CTP to the outer side surface of the color conversion pattern CVP. The second tangent line may be defined as a tangent line drawn from the contact portion CTP to the upper surface of the bank protection layer BPVX in a direction away from the color conversion pattern CVP. In an embodiment, the tangent angle is greater than or equal to about 90 degrees and less than about 180 degrees. In are more particular embodiment, the tangent angle is greater than or equal to about 90 degrees and less than or equal to about 150 degrees. In another particular embodiment, the tangent angle is greater than or equal to about 90 degrees and less than or equal to about 120 degrees. The capping layer CAP may be disposed on the bank protection layer BPVX and the color conversion pattern CVP. In an embodiment, the capping layer CAP is entirely disposed in the first to third light emitting areas EA1, EA2, EA3 and the light blocking area BA. The capping layer CAP may cover the bank protection layer BPVX and the color conversion pattern CVP. The capping layer CAP may include an inorganic insulating material. In an embodiment, the capping layer CAP is disposed along profiles or peripheral edges of the bank protection layer BPVX and the color conversion pattern CVP.

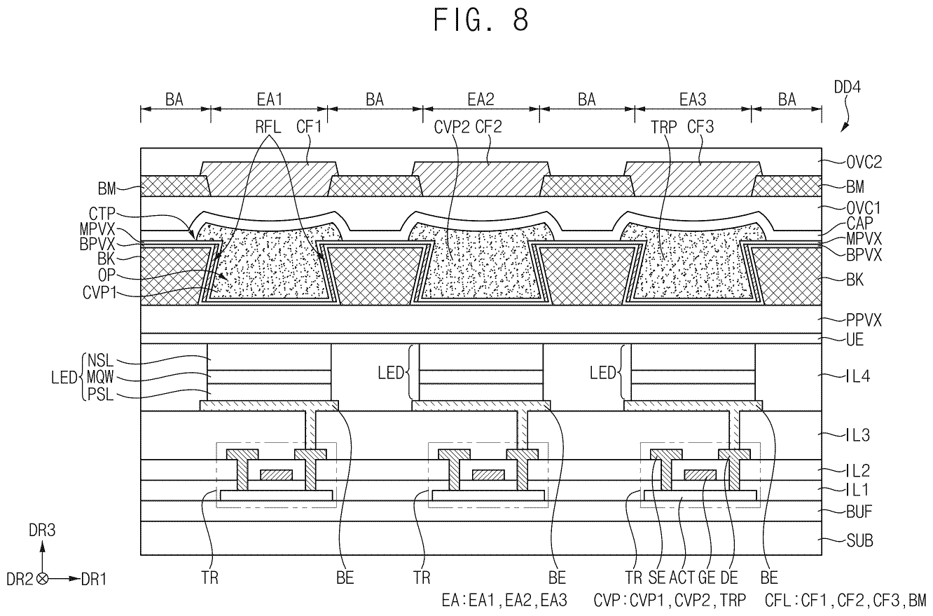

FIG. 8 is a cross-sectional view illustrating a display device according to an embodiment of the present disclosure.

Referring to FIG. 8, a display device DD4 according to an embodiment of the present disclosure includes the substrate SUB, the buffer layer BUF, the thin film transistor TR, the first to third insulating layers IL1, IL2, IL3, the lower electrode BE, the light emitting element LED, the fourth insulating layer IL4, the upper electrode UE, the pixel protection layer PPVX, the bank layer BK, the bank protection layer BPVX, the reflective film RFL, a reflective film protection layer MPVX, the color conversion pattern CVP, the capping layer CAP, the first flattening layer OVC1, the color filter layer CFL, and the second flattening layer OVC2.

The display device DD4 may be substantially the same as the display device DD described above with reference to FIGS. 1 to 4, except that the display device DD4 includes the bank protection layer BPVX covering the bank layer BK and a reflective film protection layer MPVX covering the reflective film RFL. Hereinafter, redundant descriptions of the display device DD described above with reference to FIGS. 1 to 4 may be omitted or may be summarized.

The bank protection layer BPVX may be disposed on the bank layer BK and the pixel protection layer PPVX. In an embodiment, the bank protection layer BPVX is entirely disposed in the first to third light emitting areas EA1, EA2, EA3 and the light blocking area BA. The bank protection layer BPVX may cover an upper surface of the bank layer BK and a side surface of the bank layer BK. In an embodiment, the bank protection layer BPVX includes an inorganic insulating material. In an embodiment, the bank protection layer BPVX is disposed along the profiles or peripheral edges of the bank layer BK and the pixel protection layer PPVX.

The reflective layer RFL may be disposed between the bank protection layer BPVX and the color conversion pattern CVP. The reflective film RFL may contact a side surface of the bank protection layer BPVX. In an embodiment, the reflective film RFL includes a metal having a high light reflectivity. The reflective film RFL may increase light efficiency.

The reflective film protection layer MPVX may be disposed between the reflective film RFL and the color conversion pattern CVP. The reflective film protection layer MPVX may cover the reflective film RFL. In an embodiment, the reflective film protection layer MPVX includes an inorganic insulating material. For example, the reflective film protection layer MPVX may include silicon oxide (SiOₓ), silicon nitride (SiNₓ), silicon oxynitride (SiOₓN_{y}), etc. These may be used alone or in combination with each other. However, the present disclosure is not limited thereto. The reflective film protection layer MPVX may protect the reflective film RFL from a developer used in the process of forming the color conversion pattern CVP.

In an embodiment, as illustrated in FIG. 8, the reflective film protection layer MPVX is disposed on the bank protection layer BPVX. The reflective film protection layer MPVX may be disposed along the profiles or peripheral edges of the bank protection layer BPVX and the reflective film RFL. In this case, the reflective film protection layer MPVX may be entirely disposed in the first to third light emitting areas EA1, EA2, EA3 and the light blocking area BA. The reflective film protection layer MPVX may cover the bank protection layer BPVX and the reflective film RFL. However, the present disclosure is not limited thereto. In other embodiments, the reflective film protection layer MPVX is not disposed on an upper surface of the bank protection layer BPVX. In an embodiment where the reflective film protection layer MPVX is not disposed on the upper surface, the reflective film protection layer MPVX covers the reflective film RFL and does not cover the bank protection layer BPVX.

The color conversion pattern CVP may be disposed inside the openings OP defined by the bank layer BK. In this case, an outer side surface of the color conversion pattern CVP may include a contact portion CTP that contacts an upper surface of the reflective film protection layer MPVX. Here, the upper surface of the reflective film protection layer MPVX may refer to a surface that is disposed on the bank layer BK and is parallel to an upper surface of the bank layer BK. The outer side surface of the color conversion pattern CVP may at least partially overlap the bank layer BK in a plan view.

A tangent angle may be defined as an angle between a first tangent line and a second tangent line. The first tangent line may be defined as a tangent line drawn from the contact portion CTP to the outer side surface of the color conversion pattern CVP. The second tangent line may be defined as a tangent line drawn from the contact portion CTP to the upper surface of the reflective film protection layer MPVX in a direction away from the color conversion pattern CVP. In an embodiment, the tangent angle is greater than or equal to about 90 degrees and less than about 180 degrees. In a more particular embodiment, the tangent angle is greater than or equal to about 90 degrees and less than or equal to about 150 degrees. In another more particular embodiment, the tangent angle is greater than or equal to about 90 degrees and less than or equal to about 120 degrees.

The capping layer CAP may be disposed on the reflective film protection layer MPVX and the color conversion pattern CVP. In an embodiment, the capping layer CAP is entirely disposed in the first to third light emitting areas EA1, EA2, EA3 and the light blocking area BA. The capping layer CAP may cover the reflective film protection layer MPVX and the color conversion pattern CVP. The capping layer CAP may include an inorganic insulating material. In an embodiment, the capping layer CAP is disposed along the profiles or periphery edges of the reflective film protection layer MPVX and the color conversion pattern CVP.

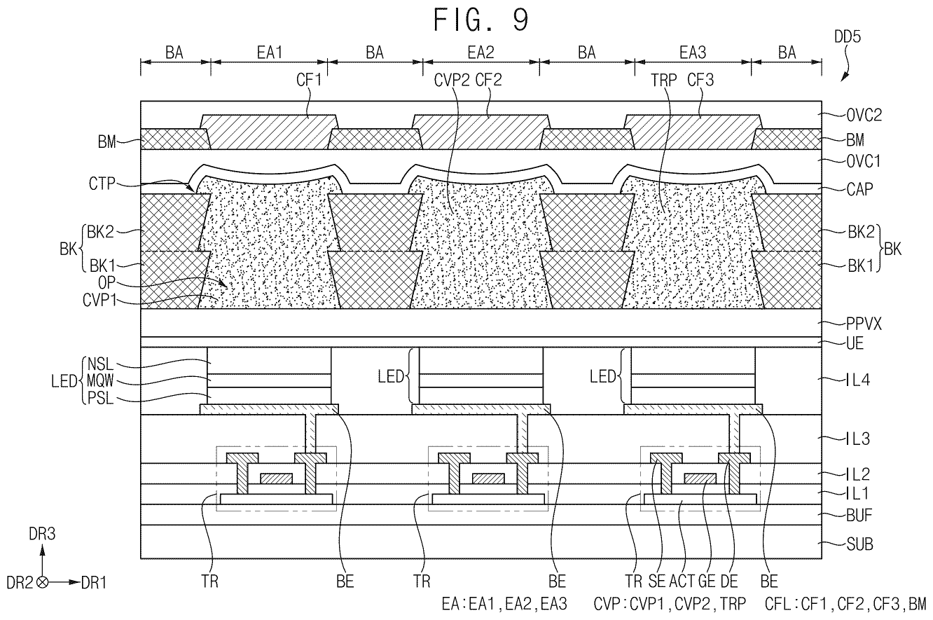

FIG. 9 is a cross-sectional view illustrating a display device according to an embodiment of the present disclosure.

Referring to FIG. 9, a display device DD5 according to an embodiment of the present disclosure includes the substrate SUB, the buffer layer BUF, the thin film transistor TR, the first to third insulating layers IL1, IL2, IL3, the lower electrode BE, the light emitting element LED, the fourth insulating layer IL4, the upper electrode UE, the pixel protection layer PPVX, a bank layer BK, the color conversion pattern CVP, the capping layer CAP, the first flattening layer OVC1, the color filter layer CFL, and the second flattening layer OVC2. In an embodiment, the bank layer BK includes a first bank layer BK1 and a second bank layer BK2 disposed on the first bank layer BK1.

The display device DD5 may be substantially the same as the display device DD described above with reference to FIGS. 1 to 4, except that the bank layer BK has a multi-layer structure. Hereinafter, redundant descriptions of the display device DD described above with reference to FIGS. 1 to 4 may be omitted or may be summarized.

The bank layer BK may be disposed in the light blocking area BA on the pixel protection layer PPVX. The bank layer BK may define a plurality of openings OP partitioning the first to third light emitting areas EA1, EA2, EA3. Accordingly, the bank layer BK may be disposed in the light blocking area BA and may not be disposed in the first to third light emitting areas EA1, EA2, EA3.

The bank layer BK may include the first bank layer BK1 and the second bank layer BK2 disposed on the first bank layer BK1. For example, each of the first bank layer BK1 and the second bank layer BK2 may have a reverse-taper cross-sectional shape. In this case, a width of an upper surface of the first bank layer BK1 may be greater than a width of a lower surface of the first bank layer BK1. A width of an upper surface of the second bank layer BK2 may be greater than a width of a lower surface of the second bank layer BK2. In an embodiment, the width of the upper surface of the first bank layer BK1 is greater than the width of the lower surface of the second bank layer BK2. However, the present disclosure is not limited thereto. A side of the color conversion pattern CVP that is adjacent to the first bank layer BK1 and the second bank layer BK2 may be tapered similar to the first bank layer BK1 and the second bank layer BK2.

The display device DD5 may further include a reflective film (e.g., the reflective film RFL of FIG. 2) that increases light efficiency. In this case, the reflective film may be disposed between the bank layer BK and the color conversion pattern CVP. The reflective film may contact a side surface of the first bank layer BK1 and a side surface of the second bank layer BK2.

The display device DD5 may further include a bank protection layer (e.g., the bank protection layer BPVX of FIG. 7) covering the bank layer BK. Specifically, the bank protection layer may be disposed on the bank layer BK and the pixel protection layer PPVX. The bank protection layer may be entirely disposed in the first to third light emitting areas EA1, EA2, EA3 and the light blocking area BA. The bank protection layer may cover the side surface of the first bank layer BK1, the side surface of the second bank layer BK2, and the upper surface of the second bank layer BK2.

The color conversion pattern CVP may be disposed inside the openings OP defined by the bank layer BK. In this case, an outer side surface of the color conversion pattern CVP may include a contact portion CTP that contacts the upper surface of the second bank layer BK2. The outer side surface of the color conversion pattern CVP may at least partially overlap the first bank layer BK1 and the second bank layer BK2 in a plan view.

A tangent angle may be defined as an angle between a first tangent line and a second tangent line. The first tangent line may be defined as a tangent line drawn from the contact portion CTP to the outer side surface of the color conversion pattern CVP. The second tangent line may be defined as a tangent line drawn from the contact portion CTP to the upper surface of the second bank layer BK2 in a direction away from the color conversion pattern CVP. In an embodiment, the tangent angle is greater than or equal to about 90 degrees and less than about 180 degrees. In a more particular embodiment, the tangent angle is greater than or equal to about 90 degrees and less than or equal to about 150 degrees. In another more particular embodiment, the tangent angle is greater than or equal to about 90 degrees and less than or equal to about 120 degrees.

The capping layer CAP may be disposed on the second bank layer BK2 and the color conversion pattern CVP. In an embodiment, the capping layer CAP is entirely disposed in the first to third light emitting areas EA1, EA2, EA3 and the light blocking area BA. The capping layer CAP may cover the second bank layer BK2 and the color conversion pattern CVP. The capping layer CAP may include an inorganic insulating material. In an embodiment, the capping layer CAP is disposed along the profiles or periphery edges of the second bank layer BK2 and the color conversion pattern CVP.

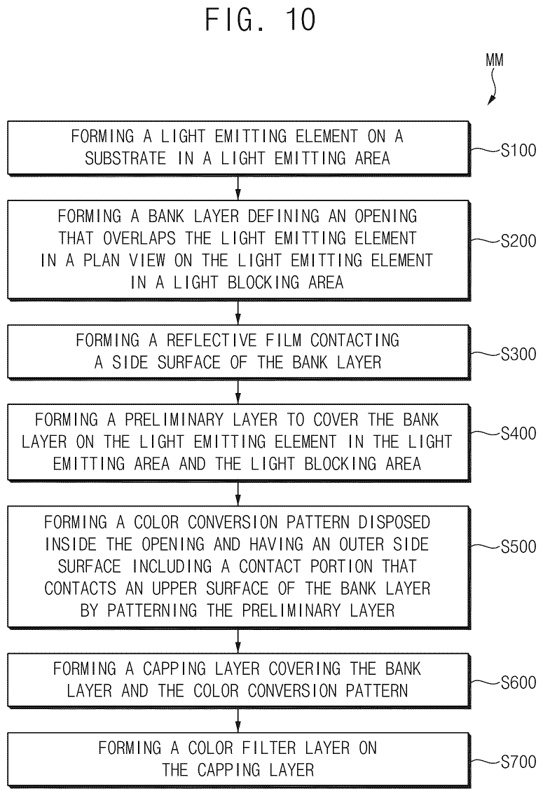

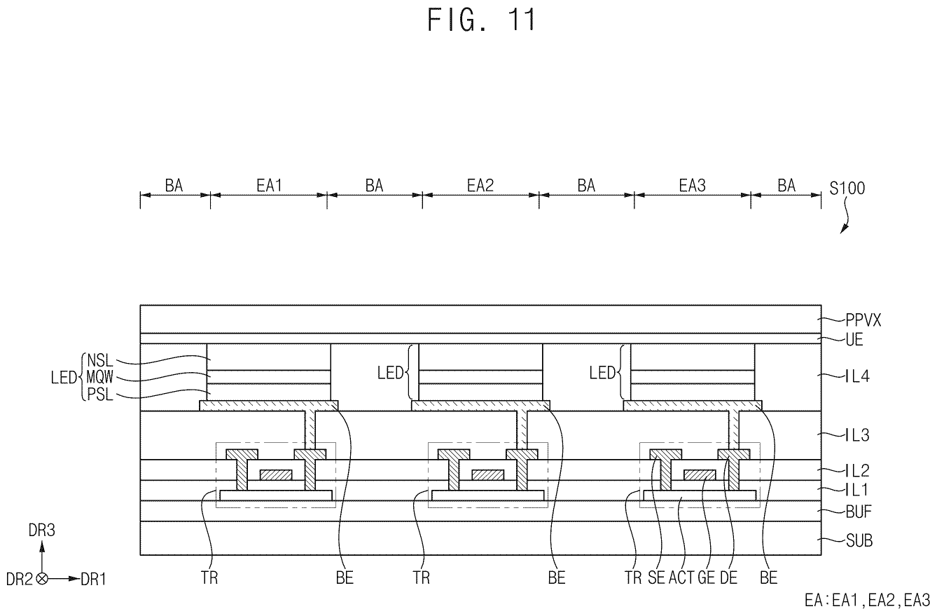

FIG. 10 is a flowchart of a method of manufacturing a display device according to an embodiment of the present disclosure. FIGS. 11, 12, 13, 14, 15, 16, 17, 18, and 19 are cross-sectional views illustrating the method of manufacturing the display device of FIG. 10.

The method of manufacturing the display device MM described below with reference to FIGS. 11 to 19 may be a method of manufacturing the display device DD described above with reference to FIG. 2. Hereinafter, redundant descriptions of the display device DD described above with reference to FIG. 2 may be omitted or may be summarized.

Referring to FIGS. 2 and 10, a method MM of manufacturing a display device according to an embodiment of the present disclosure includes forming the light emitting element LED on the substrate SUB in a light emitting area EA (S100), forming a bank layer BK defining an opening OP that overlaps the light emitting element LED in a plan view on the light emitting element LED in a light blocking area BA (S200), forming a reflective film RFL contacting a side surface of the bank layer BK (S300), forming a preliminary layer to cover the bank layer BK on the light emitting element LED in the light emitting area EA and the light blocking area BA (S400), forming a color conversion pattern CVP disposed inside the opening OP and having an outer side surface including a contact portion CTP that contacts an upper surface of the bank layer BK by patterning the preliminary layer (S500), forming a capping layer CAP covering the bank layer BK and the color conversion pattern CVP (S600), and forming a color filter layer CFL on the capping layer CAP (S700).

Referring to FIG. 11, the light emitting element LED may be formed on the substrate SUB in the light emitting area EA (S100).

The buffer layer BUF may be formed on the substrate SUB, and the thin film transistor TR may be formed on the buffer layer BUF. The thin film transistor TR may include the active pattern ACT, the gate electrode GE, the source electrode SE, and the drain electrode DE. The first insulating layer IL1 may be formed to cover the active pattern ACT on the buffer layer BUF. The second insulating layer IL2 may be formed to cover the gate electrode GE on the first insulating layer IL1. The third insulating layer IL3 may be formed to cover the source electrode SE and the drain electrode DE on the second insulating layer IL2.

The lower electrode BE may be formed on the third insulating layer IL3. The light emitting element LED may be formed on the lower electrode BE. The light emitting element LED may be disposed in the light emitting area EA. Specifically, the light emitting element LED may be disposed in each of the first light emitting area EA1, the second light emitting area EA2, and the third light emitting area EA3. The light emitting element LED may include the first semiconductor layer PSL, the active layer MQW, and the second semiconductor layer NSL. The fourth insulating layer IL4 may be formed to cover the lower electrode BE and the light emitting element LED on the third insulating layer IL3. The upper electrode UE may be formed on the second semiconductor layer NSL and the fourth insulating layer IL4. The pixel protection layer PPVX may be formed on the upper electrode UE.

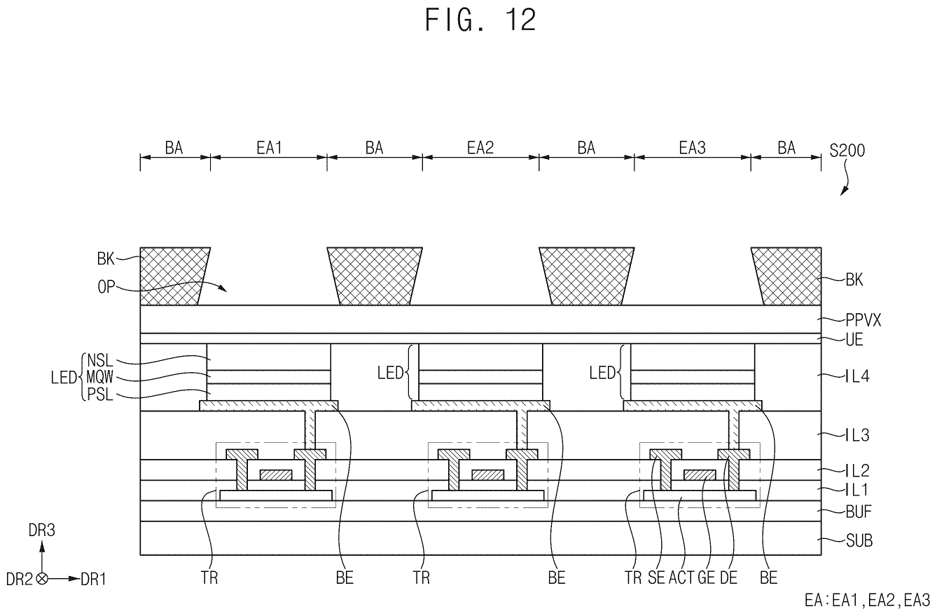

Referring to FIG. 12, the bank layer BK defining the opening OP that overlaps the light emitting element LED in a plan view may be formed on the light emitting element LED in the light blocking area BA (S200).

The bank layer BK may be formed on the light emitting element LED in the light blocking area BA. Specifically, the bank layer BK may be formed on the pixel protection layer PPVX in the light blocking area BA. The bank layer BK may define the plurality of openings OP that partition the first to third light emitting areas EA1, EA2, EA3. The bank layer BK may include an inorganic material or an organic material including a light blocking material with a black color. The light blocking area BA may include several light blocking regions that are spaced apart from one another in the first direction DR1 and the bank layer BK may include several portions spaced apart from one another and disposed respectively in the light blocking regions,

In an embodiment, as illustrated in FIG. 12, the bank layer BK may have a single-layer structure. However, the present disclosure is not limited thereto. In other embodiments, the bank layer BK may have a multi-layer structure. For example, the bank layer BK may include a first bank layer (e.g., the first bank layer BK1 of FIG. 9) and a second bank layer (e.g., the second bank layer BK2 of FIG. 9) disposed on the first bank layer.

In an embodiment, a bank protection layer (e.g., the bank protection layer BPVX of FIG. 7) is formed on the bank layer BK and the pixel protection layer PPVX. The bank protection layer may be entirely formed in the first to third light emitting areas EA1, EA2, EA3 and the light blocking area BA. The bank protection layer may cover the upper surface of the bank layer BK and a side surface of the bank layer BK. The bank protection layer may include an inorganic insulating material. The bank protection layer may be formed along the profiles or peripheral edges of the bank layer BK and the pixel protection layer PPVX.

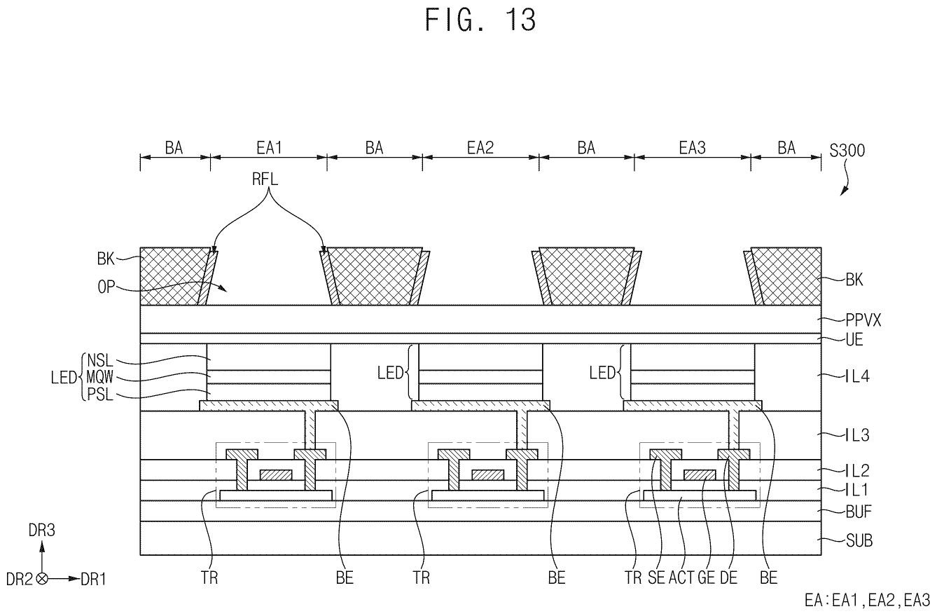

Referring to FIG. 13, the reflective film RFL contacting the side surface of the bank layer BK may be formed (S300).

The reflective film RFL may be formed inside the opening OP defined by the bank layer BK. Specifically, the reflective film RFL may contact the side surface of the bank layer BK. In an embodiment, the reflective film RFL includes a metal having a high light reflectivity. For example, the reflective film RFL may include aluminum (Al) or silver (Ag), but the present disclosure is not limited thereto. In other embodiments, instead of the reflective film RFL including a metal, a reflective bank (e.g., the reflective bank SBK of FIG. 6) including scattering particles may be formed on the side surface of the bank layer BK. The reflective bank may include the scattering particles and a photosensitive polymer in which the scattering particles are dispersed.

In an embodiment, a reflective film protection layer (e.g., the reflective film protection layer MPVX of FIG. 8) covering the reflective film RFL is formed. In an embodiment, the reflective film protection layer is entirely formed in the first to third light emitting areas EA1, EA2, EA3 and the light blocking area BA. The reflective film protection layer may include an inorganic insulating layer. The reflective film protection layer may be formed along the profiles or peripheral edges of the bank layer BK, the reflective film RFL, and the pixel protective layer PPVX.

Referring to FIG. 14, a preliminary layer PRE may be formed to cover the bank layer BK on the light emitting element LED in the light emitting area EA and the light blocking area BA (S400).

Specifically, the preliminary layer PRE may be formed to cover the bank layer BK on the pixel protection layer PPVX in the light emitting area EA and the light blocking area BA. The preliminary layer PRE may be entirely formed in the first to third light emitting areas EA1, EA2, EA3 and the light blocking area BA. The preliminary layer PRE may include quantum dots, scattering particles, and a photosensitive polymer in which the scattering particles are dispersed. The quantum dots may be excited by light emitted from the light emitting element LED and may emit light of a second color. For example, the light of the second color may be green light, but the present disclosure is not limited thereto. For example, space between the reflective films RFL, space above portions of the bank layer BK and space above the reflective films RFL may be filled with the preliminary layer PRE.

In exemplary embodiments, the preliminary layer PRE includes a photosensitive organic material. For example, the preliminary layer PRE may include a positive photosensitive organic material.

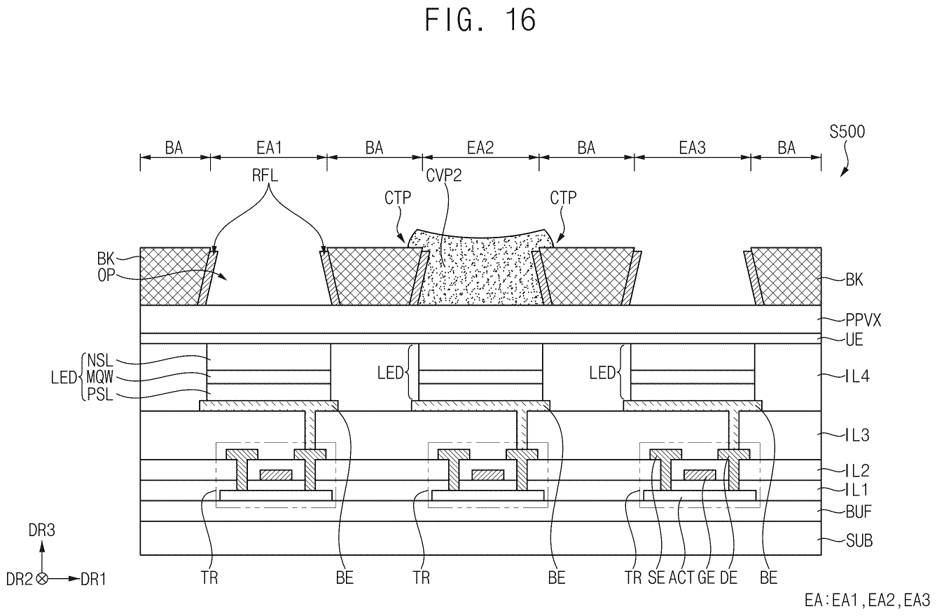

Referring to FIGS. 15, 16, and 17, the color conversion pattern CVP disposed inside the opening OP and having an outer side surface including the contact portion CTP that contacts the upper surface of the bank layer BK may be formed by patterning the preliminary layer PRE (S500).

As illustrated in FIG. 15, the preliminary layer PRE may be exposed using a photomask PM. The photomask PM may be divided into a blocking area EBA and a transmission area ETA according to the light transmittance. The light transmittance of the blocking area EBA may be smaller than the light transmittance of the transmission area ETA.

The photomask PM may block light provided from the outside in the blocking area EBA so as to prevent the light from reaching a portion of the preliminary layer PRE overlapping the blocking area EBA. The photomask PM may transmit light provided from the outside in the transmission area ETA so as to allow the light to reach a portion of the preliminary layer PRE overlapping the transmission area ETA.

As illustrated in FIG. 16, the second color conversion pattern CVP2 may be formed by developing the exposed preliminary layer PRE.

Using a predetermined developer, one of light-exposed portion and light-blocked portion of the preliminary layer PRE may be selectively removed depending on the change in chemical properties. For example, when the preliminary layer PRE includes a positive photosensitive organic material, the light-blocked portion may remain in a cured state and may not dissolve in the developer. In other words, through the development process, the light-exposed portion may be selectively removed, and the light-blocked portion may not be removed.

Accordingly, the second color conversion pattern CVP2 may be formed by developing the exposed preliminary layer PRE. The second color conversion pattern CVP2 may be formed inside the opening OP in the second light emitting area EA2. The second color conversion pattern CVP2 may overlap the light emitting element LED in the second light emitting area EA2 in a plan view. An outer side surface of the second color conversion pattern CVP2 may include the contact portion CTP that contacts the upper surface of the bank layer BK. The outer side surface of the second color conversion pattern CVP2 may at least partially overlap the bank layer BK in a plan view. The second color conversion pattern CVP2 may correspond to the second color conversion pattern CVP2 of FIG. 2.

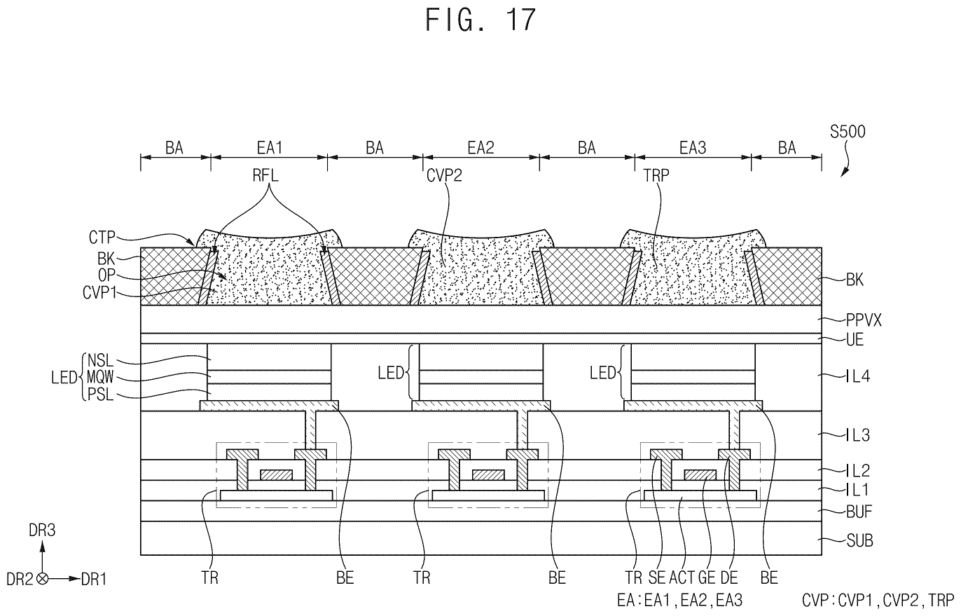

As illustrated in FIG. 17, by repeatedly performing the process of forming the preliminary layer PRE and the process of exposing and developing the preliminary layer PRE, the first color conversion pattern CVP1 overlapping the first light emitting area EA1 and the transmission pattern TRP overlapping the third light emitting area EA3 may be formed. Accordingly, the color conversion pattern CVP including the first color conversion pattern CVP1, the second color conversion pattern CVP2, and the transmission pattern TRP may be formed.

A tangent angle may be defined as an angle between a first tangent line (or first tangent) and a second tangent line (or second tangent). The first tangent line may be defined as a tangent line drawn from the contact portion CTP to the outer side surface of the color conversion pattern CVP. For example, a first tangent may be from the contact portion CTP to the outer side surface of the color conversion pattern CVP. The second tangent line may be defined as a tangent line drawn from the contact portion CTP to the upper surface of the bank layer BK in a direction away from the color conversion pattern CVP. For example, the second tangent line may be defined as a tangent line drawn in the first direction DR1 from the contact portion CTP to a point on the upper surface of the bank layer BK. For example, a second tangent may be from the contact portion CTP to the upper surface of the bank layer BK in a direction away from the color conversion pattern CVP. In an embodiment, the tangent angle is greater than or equal to about 90 degrees and less than about 180 degrees. In a more particular embodiment, the tangent angle is greater than or equal to about 90 degrees and less than or equal to about 150 degrees. In another More particular embodiment, the tangent angle is greater than or equal to about 90 degrees and less than or equal to about 120 degrees.

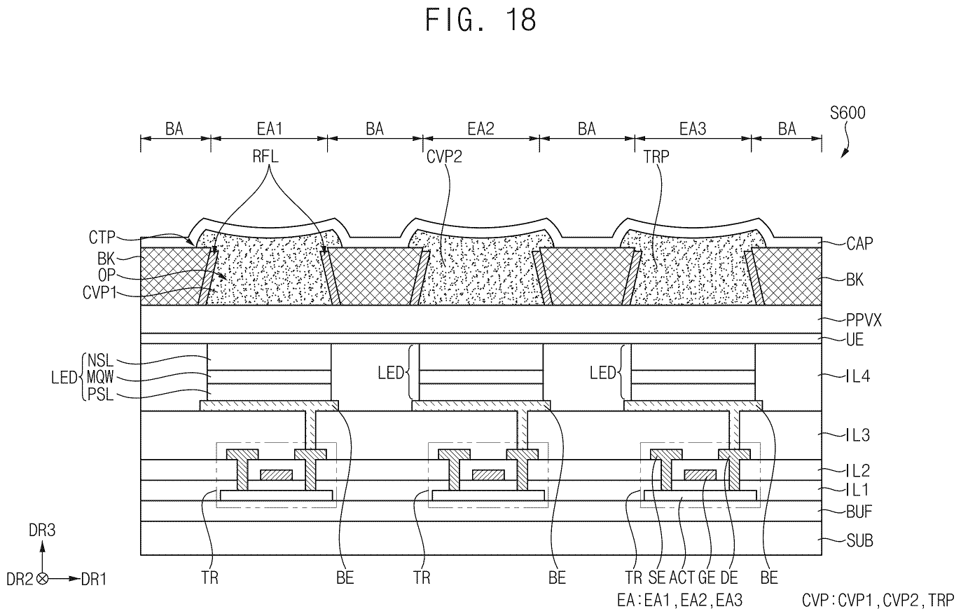

Referring to FIG. 18, the capping layer CAP covering the bank layer BK and the color conversion pattern CVP may be formed (S600).

The capping layer CAP may be formed on the bank layer BK and the color conversion pattern CVP. In an embodiment, the capping layer CAP is entirely formed on the first to third light emitting areas EA1, EA2, EA3 and the light blocking area BA. The capping layer CAP may cover the bank layer BK and the color conversion pattern CVP. The capping layer CAP may include an inorganic insulating material. The capping layer CAP may be formed along the profiles or peripheral edges of the bank layer BK and the color conversion pattern CVP.

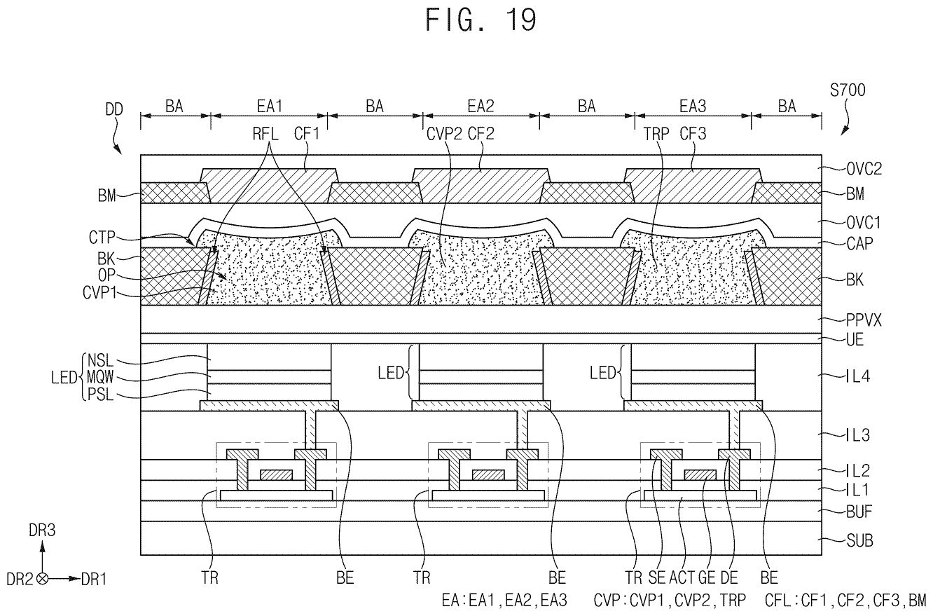

Referring to FIG. 19, the color filter layer CFL may be formed on the capping layer CAP (S700).

The first flattening layer OVC1 may be formed on the capping layer CAP. The first flattening layer OVC1 may include an inorganic insulating material and/or an organic insulating material. The first flattening layer OVC1 may flatten a step formed by the bank layer BK and the color conversion pattern CVP.

The color filter layer CFL may be formed on the first flattening layer OVC1. The color filter layer CFL may include the first to third color filters CF1, CF2, CF3 and the light blocking pattern BM. The light blocking pattern BM may define a plurality of openings that partition the first to third light emitting areas EA1, EA2, EA3. Accordingly, the light blocking pattern BM may be disposed in the blocking area BA and may not be disposed in the first to third light emitting areas EA1, EA2, EA3.

The first to third color filters CF1, CF2, CF3 may be disposed inside the openings defined by the light blocking pattern BM, respectively. The first color filter CF1 may overlap the light emitting element LED in the first light emitting area EA1 in a plan view. The second color filter CF2 may overlap the light emitting element LED in the second light emitting area EA2 in a plan view. The third color filter CF3 may overlap the light emitting element LED in the third light emitting area EA3 in a plan view.

The second flattening layer OVC2 may be formed on the color filter layer CFL. The second flattening layer OVC2 may include an inorganic insulating material and/or an organic insulating material. The second flattening layer OVC2 may flatten a step formed by the color filter layer CFL.

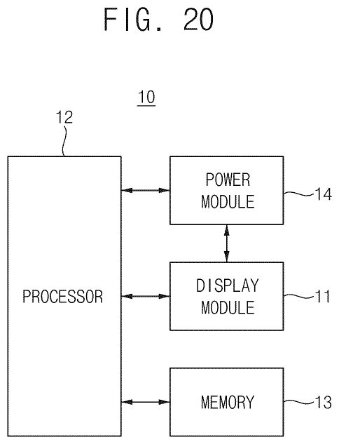

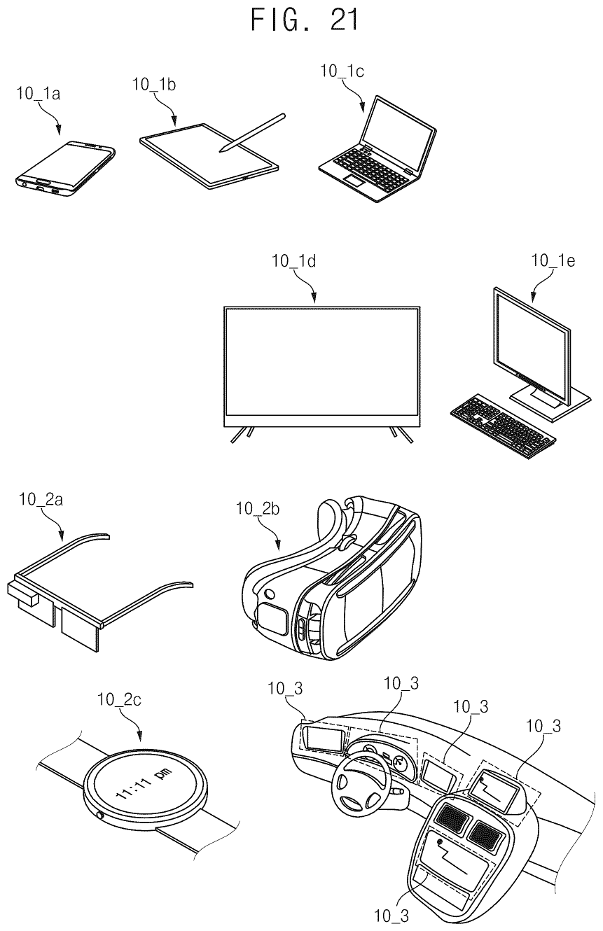

FIG. 20 is a block diagram of an electronic device according to an embodiment of the present disclosure.

Referring to FIG. 20, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information required for operation of the processor 12 or the display module 11. When the processor 12 executes an application stored in the memory 13, an image data signal and/or a input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

FIG. 21 is a schematic diagram of an electronic device according to various embodiments.

Referring to FIG. 21, various electronic devices to which a display device according to the embodiments is applied may include image display electronic devices such as a smartphones 10_1a, a tablet PC 10_1b, a laptop 10_1c, a television 10_1d, a desk monitor 10_1e, etc., wearable electronic devices including display modules such as a smart glasses 10_2a, a head-mounted display 10_2b, and a smart watch 10_2c, etc., and vehicle electronic devices (10_3) including display modules such as a CID (center information display) which may be disposed on a instrument panel, a center fascia, and a dashboard of an automobile and a room mirror display, etc.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure.

What is claimed is:

1. A display device comprising:
a substrate including a light emitting area and a light blocking area surrounding the light emitting area;
a light emitting element disposed on the substrate in the light emitting area;
a bank layer disposed on the light emitting element in the light blocking area and defining an opening overlapping the light emitting element in a plan view;
a color conversion pattern disposed inside the opening on the light emitting element in the light emitting area and having an outer side surface including a contact portion that contacts an upper surface of the bank layer; and
a capping layer covering the bank layer and the color conversion pattern,
wherein an angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

2. The display device of claim 1, wherein the outer side surface of the color conversion pattern at least partially overlaps the bank layer in the plan view.

3. The display device of claim 1, wherein the color conversion pattern includes a photosensitive organic material.

4. The display device of claim 1, wherein the capping layer includes an inorganic insulating material.

5. The display device of claim 4, wherein the capping layer is disposed along profiles of the bank layer and the color conversion pattern.

6. The display device of claim 1, further comprising:
a reflective film disposed between the bank layer and the color conversion pattern, wherein the reflective film includes a metal.

7. The display device of claim 6, further comprising:
a reflective film protection layer disposed between the reflective film and the color conversion pattern.

8. The display device of claim 1, further comprising:
a reflective bank disposed between the bank layer and the color conversion pattern and including a scattering particle.

9. The display device of claim 1,
wherein the bank layer includes a first bank layer and a second bank layer disposed on the first bank layer,
wherein the outer side surface of the color conversion pattern includes the contact portion that contacts an upper surface of the second bank layer, and
wherein the second tangent line is a tangent from the contact portion to the upper surface of the second bank layer in the direction away from the color conversion pattern.

10. The display device of claim 1, wherein the light emitting element comprises:
a first semiconductor layer disposed on the substrate;
an active layer disposed on the first semiconductor layer; and
a second semiconductor layer disposed on the active layer.

11. The display device of claim 1,
wherein the light emitting area includes a first light emitting area, a second light emitting area, and a third light emitting area that emit lights of different colors,
wherein the light emitting element is disposed in each of the first light emitting area, the second light emitting area, and the third light emitting area, and
wherein the color conversion pattern includes a first color conversion pattern overlapping the light emitting element in the first light emitting area in the plan view, a second color conversion pattern overlapping the light emitting element in the second light emitting area in the plan view, and a transmission pattern overlapping the light emitting element in the third light emitting area in the plan view.

12. The display device of claim 11,
wherein the first color conversion pattern converts light emitted from the light emitting element into light of a first color,
wherein the second color conversion pattern converts the light emitted from the light emitting element into light of a second color, and
wherein the transmission pattern transmits the light emitted from the light emitting element.

13. A display device comprising:
a substrate including a light emitting area and a light blocking area surrounding the light emitting area;
a light emitting element disposed on the substrate in the light emitting area;
a bank layer disposed on the light emitting element in the light blocking area and defining an opening overlapping the light emitting element in a plan view;
a bank protection layer covering an upper surface of the bank layer and a side surface of the bank layer;
a color conversion pattern disposed inside the opening on the light emitting element in the light emitting area and having an outer side surface including a contact portion that contacts an upper surface of the bank protection layer; and
a capping layer covering the bank protection layer and the color conversion pattern,
wherein an angle between a first tangent from the contact portion to the outer side surface of the color conversion pattern and a second tangent from the contact portion to the upper surface of the bank protection layer in a direction away from the color conversion pattern is greater than or equal to about 90 degrees and less than about 180 degrees.

14. The display device of claim 13, wherein the outer side surface of the color conversion pattern at least partially overlaps the bank layer in the plan view.

15. The display device of claim 13, wherein the capping layer includes an inorganic insulating material.

16. The display device of claim 15, wherein the capping layer is disposed along profiles of the bank protection layer and the color conversion pattern.

17. The display device of claim 13, further comprising:
a reflective film disposed between the bank protection layer and the color conversion pattern, wherein the reflective film includes a metal.

18. The display device of claim 17, further comprising:
a reflective film protection layer disposed between the reflective film and the color conversion pattern.

19. The display device of claim 13,
wherein the bank layer includes a first bank layer and a second bank layer disposed on the first bank layer, and
wherein the bank protection layer covers a side surface of the first bank layer, a side surface of the second bank layer, and an upper surface of the second bank layer.

20. A method of manufacturing a display device, the method comprising:
forming a light emitting element on a substrate in a light emitting area;
forming a bank layer on the substrate in a light blocking area to define an opening that overlaps the light emitting element in a plan view;
forming a preliminary layer to cover the bank layer;
patterning the preliminary layer to form a color conversion pattern disposed inside the opening and having an outer side surface including a contact portion that contacts an upper surface of the bank layer; and
forming a capping layer covering the bank layer and the color conversion pattern,
wherein an angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.

21. The method of claim 20, wherein the patterning the preliminary layer comprises:
exposing the preliminary layer; and
developing the exposed preliminary layer to form the color conversion pattern.

22. The method of claim 20, wherein the capping layer includes an inorganic insulating material.

23. The method of claim 20, wherein the capping layer is formed along profiles of the bank layer and the color conversion pattern.

24. The method of claim 20, further comprising:
forming a reflective film to contact a side surface of the bank layer and include a metal before forming the preliminary layer.

25. The method of claim 24, further comprising:
forming a reflective film protection layer covering the reflective film before forming the preliminary layer.

26. The method of claim 20, further comprising:
forming a reflective bank to contact a side surface of the bank layer and include a scattering particle before forming the preliminary layer.

27. The method of claim 20, wherein the light emitting element comprises:
a first semiconductor layer disposed on the substrate;
an active layer disposed on the first semiconductor layer; and
a second semiconductor layer disposed on the active layer.

28. An electronic device comprising:
a display device including a light emitting element; and
a power module configured to provide power to the display device,
wherein the display device comprises:
a substrate including a light emitting area and a light blocking area surrounding the light emitting area;
the light emitting element disposed on the substrate in the light emitting area;
a bank layer disposed on the light emitting element in the light blocking area and defining an opening overlapping the light emitting element in a plan view;
a color conversion pattern disposed inside the opening on the light emitting element in the light emitting area and having an outer side surface including a contact portion that contacts an upper surface of the bank layer; and
a capping layer covering the bank layer and the color conversion pattern, and
wherein an angle between a first tangent from the contact portion to the outer side surface of the color conversion pattern and a second tangent from the contact portion to the upper surface of the bank layer in a direction away from the color conversion pattern is greater than or equal to about 90 degrees and less than about 180 degrees.
